(19) United States
(12) Patent Application Publication
(10) Pub. No.: US 2025/0098278 A1
(43) Pub. Date: Mar. 20, 2025

(54) SEMICONDUCTOR DEVICE

(71) Applicant: SAMSUNG ELECTRONICS CO., LTD., Suwon-si (KR)

(72) Inventors: Byungho Moon, Suwon-si (KR); Donghoon Hwang, Suwon-si (KR); Hyojin Kim, Suwon-si (KR); Kyunghee Cho, Suwon-si (KR)

(21) Appl. No.: 18/815,956

(22) Filed: Aug. 27, 2024

(30) Foreign Application Priority Data
Sep. 14, 2023 (KR) 10-2023-0122144

(51) Int. Cl. H01L 21/8238; H01L 27/092; H01L 29/06; H01L 29/08; H01L 29/423; H01L 29/66; H01L 29/775; H01L 29/786

(52) U.S. Cl. CPC H10D 84/038; H10D 30/014; H10D 30/43; H10D 30/6735; H10D 30/6757; H10D 62/115; H10D 62/121; H10D 62/151; H10D 64/017; H10D 84/0167; H10D 84/0181; H10D 84/0186; H10D 84/85

(57) ABSTRACT

A semiconductor device includes a substrate, lower channel layers spaced apart from each other in a vertical direction perpendicular to an upper surface of the substrate and extending in the first direction, upper channel layers on the lower channel layers, respectively, and spaced apart from each other in the vertical direction, a middle dielectric isolation structure between an uppermost lower channel layer among the lower channel layers and a lowermost upper channel layer among the upper channel layers, a lower gate structure on the lower channel layers; an upper gate structure on the upper channel layers on the lower gate structure and extending in a second direction perpendicular to the first direction. a gate isolation insulating layer between the lower gate structure and the upper gate structure, in contact with a side surface of the middle dielectric isolation structure, and extending around the lower gate structure.

### CROSS-REFERENCE TO RELATED APPLICATION(S)

This application claims benefit of priority to Korean Patent Application No. 10-2023-0122144 filed on Sep. 14, 2023 in the Korean Intellectual Property Office, the disclosure of which is incorporated herein by reference in its entirety.

### BACKGROUND

Example embodiments of the present disclosure relate to a semiconductor device.

As demands for high performance, speed, and/or multifunctionality in a semiconductor device have increased, it has been necessary to increase integration density of a semiconductor device.

### SUMMARY

Example embodiments of the present disclosure provide a semiconductor device having increased integration density and improved reliability.

According to example embodiments of the present disclosure, a semiconductor device includes a substrate, lower channel layers spaced apart from each other in a vertical direction perpendicular to an upper surface of the substrate and extending in the first direction parallel to the upper surface of the substrate, upper channel layers on the lower channel layers and spaced apart from each other in the vertical direction, a middle dielectric isolation structure between an uppermost lower channel layer among the lower channel layers and a lowermost upper channel layer among the upper channel layers, a lower gate structure on the lower channel layers, an upper gate structure on the upper channel layers and extends in a second direction perpendicular to the first direction, a gate isolation insulating layer between the lower gate structure and the upper gate structure, in contact with a side surface of the middle dielectric isolation structure on the lower gate structure, and on at least a portion of the lower gate structure, a lower source/drain region on at least one side of the lower gate structure and electrically connected to the lower channel layers, an upper source/drain region electrically connected to each of the upper channel layers on at least one side of the upper gate structure and spaced apart from the lower source/drain region in the vertical direction, and a barrier structure between the lower source/drain region and the upper source/drain region.

According to example embodiments of the present disclosure, a semiconductor device includes a substrate, first lower channel layers spaced apart from each other in a vertical direction perpendicular to an upper surface of the substrate and extending in the first direction parallel to the upper surface of the substrate, first upper channel layers on the first lower channel layers, and spaced apart from each other in the vertical direction, a first middle dielectric isolation structure between an uppermost lower channel layer among the first lower channel layers and a lowermost upper channel layer among the first upper channel layers, a first lower gate structure including a lower gate electrode on the first lower channel layers, a first upper gate structure on the first upper channel layers and extends in a second direction perpendicular to the first direction, a first lower gate isolation insulating layer between the first lower gate structure and the first upper gate structure, a lower source/drain region on at least one side of the first lower gate structure and electrically connected to the first lower channel layers, respectively, an upper source/drain region electrically connected to each of the first upper channel layers on at least one side of the first upper gate structure and spaced apart from the lower source/drain region in the vertical direction, a barrier structure between the lower source/drain region and the upper source/drain region, a lower gate contact structure below the first lower gate structure and electrically connected to the lower gate electrode of the first lower gate structure, and a lower interconnection below the lower gate contact structure and electrically connected to the lower gate contact structure. The first lower gate isolation insulating layer is in contact with a side surface of the first middle dielectric isolation structure. The first lower gate isolation insulating layer extends along a side surface of the first lower gate structure.

According to example embodiments of the present disclosure, a semiconductor device includes a lower structure, an upper structure, middle dielectric isolation structures extending in a first direction between the lower structure and the upper structure and spaced apart from each other in a second direction perpendicular to the first direction, and a gate isolation insulating layer between at least a portion of the lower structure and at least a portion of the upper structure, and extending from a side surface of at least a portion of the middle dielectric isolation structures toward a lower end of the lower structure, wherein the lower structure includes a lower source drain regions spaced apart from each other in the first direction, lower active layers spaced apart from each other in a vertical direction, between lower source/drain regions, and electrically connected to the lower source/drain regions, and a lower gate structure including a first lower gate structure including a first lower gate electrode that extends in a second direction perpendicular to the first direction, and a second lower gate structure including a second lower gate electrode electrically insulated from the first lower gate electrode by the gate isolation insulating layer, wherein the upper structure includes upper source/drain regions spaced apart from each other in the first direction and overlapping the lower source/drain regions in the vertical direction, upper active layers spaced apart from each other in the vertical direction, between the upper source/drain regions, electrically connected to the upper source/drain regions, and overlapping the lower active layers in the vertical direction, and an upper gate structure extending in the second direction and overlapping the lower gate structure in the vertical direction. The gate isolation insulating layer is in contact with a side surface of the middle dielectric isolation structure on the second lower gate structure. The gate isolation insulating layer extends along a side surface of the second lower gate structure. A lower end of the gate isolation insulating layer is substantially a same distance from a substrate as a lower end of the second lower gate structure and a level of a lower end of the upper structure.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan diagram illustrating a semiconductor device according to example embodiments of the present disclosure;

FIG. 2 is a cross-sectional diagram illustrating a semiconductor device according to example embodiments of the present disclosure;

FIG. 3 is a cross-sectional diagram illustrating a semiconductor device according to example embodiments of the present disclosure;

FIGS. 4A, 4B, and 4C are enlarged diagram illustrating a portion of a semiconductor device according to example embodiments of the present disclosure;

FIG. 5 is a cross-sectional diagram illustrating a semiconductor device according to example embodiments of the present disclosure;

FIGS. 6A and 6B is a cross-sectional diagram illustrating a semiconductor device according to example embodiments of the present disclosure;

FIG. 7 is a cross-sectional diagram illustrating a semiconductor device according to example embodiments of the present disclosure;

FIG. 8 is a plan diagram illustrating a semiconductor device according to example embodiments of the present disclosure;

FIGS. 9 and 10 are cross-sectional diagrams illustrating a semiconductor device according to example embodiments of the present disclosure;

FIGS. 11A, 11B, 11C, 11D, 11E, 11F, 11G, 11H, 11I, 11J, 11K, 11L, 11M, and 11N are cross-sectional diagrams illustrating processes of a method of manufacturing a semiconductor device in order according to example embodiments of the present disclosure;

FIGS. 12A, 12B, 12C, 12D, and 12E are cross-sectional diagrams illustrating processes of a method of manufacturing a semiconductor device in order according to example embodiments of the present disclosure;

FIGS. 13A, 13B, 13C, 13D, and 13E are cross-sectional diagrams illustrating processes of a method of manufacturing a semiconductor device in order according to example embodiments of the present disclosure; and

FIGS. 14A, 14B, 14C, 14D, and 14E are cross-sectional diagrams illustrating processes of a method of manufacturing a semiconductor device in order according to example embodiments of the present disclosure.

### DETAILED DESCRIPTION

Hereinafter, embodiments of the present disclosure will be described as follows with reference to the accompanying drawings.

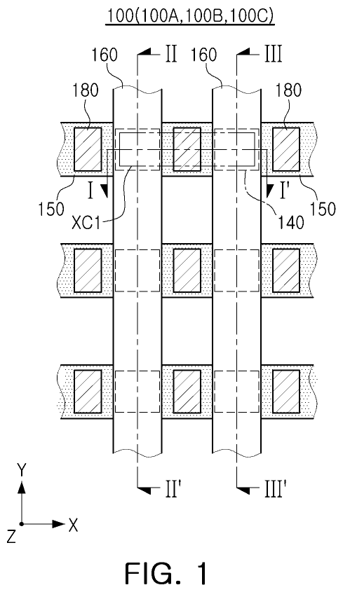

FIG. 1 is a plan diagram illustrating a semiconductor device 100, 100A, 100B, and 100C according to example embodiments.

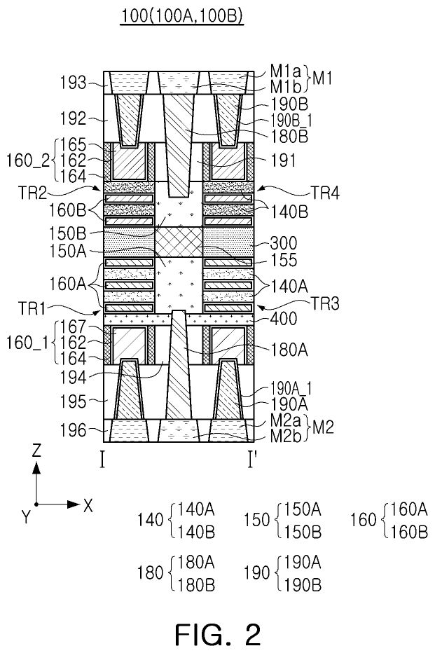

FIG. 2 is a cross-sectional diagram illustrating a semiconductor device 100, 100A, and 100B according to example embodiments, taken along line I-I′ in FIG. 1.

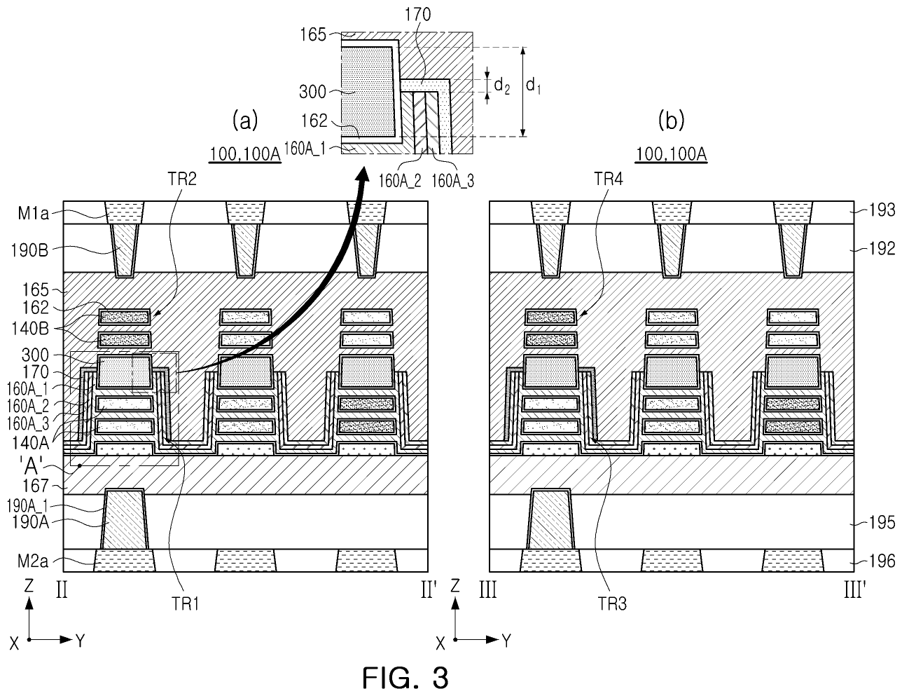

FIG. 3 is a cross-sectional diagram illustrating a semiconductor device 100, 100A taken along lines II-II′ and III-III′ in FIG. 1.

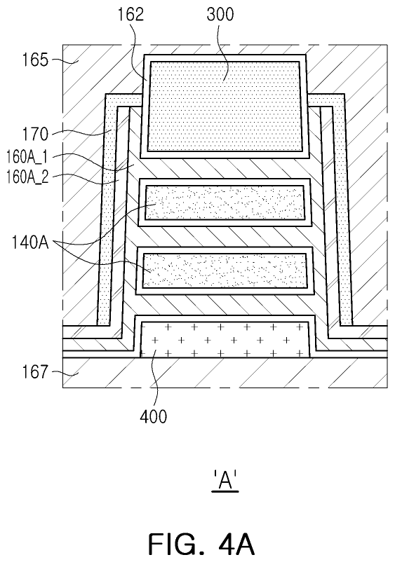

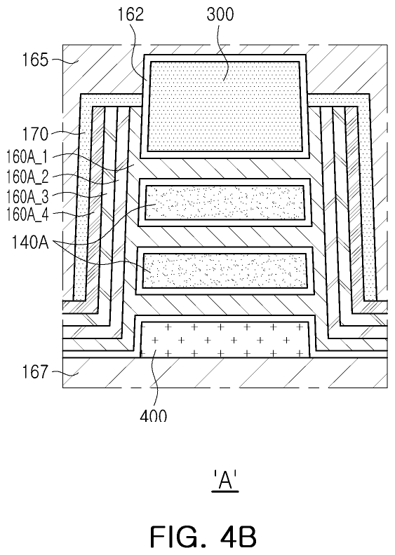

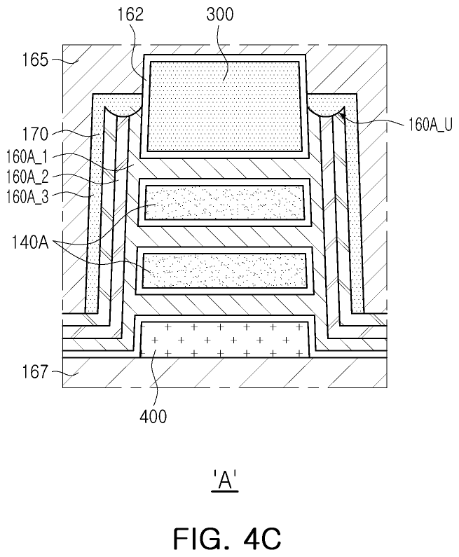

FIGS. 4A, 4B, and 4C are enlarged diagrams illustrating a semiconductor device 100 and 100A according to example embodiments, illustrating region “A” in FIG. 3.

For ease of description, FIG. 1 illustrates only a portion of components of the semiconductor device 100.

Referring to FIGS. 1 to 3, the semiconductor device 100 in example embodiments may be configured as a semiconductor structure including a first surface and a second surface, opposite to the first surface. The semiconductor device 100 in example embodiments may include a channel structure 140 including a plurality of channel layers 140A and 140B spaced apart from each other in a vertical direction perpendicular to the first surface of the semiconductor structure (or “vertical direction toward the second surface”) and extending in the first direction, for example, the X-direction, a middle dielectric isolation structure 300 disposed between lower channel layers 140A (or “lower channel structure”) and upper channel layers 140B (or “upper channel structure”), a gate structure 160 including a backside gate structure 160_1, a lower gate structure 160A, and an upper gate structure 160B or 160_2, a bottom dielectric isolation structure 400 disposed between the lowermost channel layer and the backside gate structure 160_1 among lower channel layers 140A, a source/drain regions 150 including lower source/drain regions 150A in contact with lower channel layers 140A and upper source/drain regions 150B in contact with upper channel layers 140B, a barrier structure 155 disposed between lower source/drain regions 150A and upper source/drain regions 150B, contract structures of contact plugs 180, including a lower contact plug 180A (or “backside contact plug”) and an upper contact plug 180B connected to lower source/drain regions 150A and upper source/drain regions 150B, respectively, and a gate contact structures 190 including a lower gate contact structure 190A (or “backside gate contact structure”) and an upper gate contact structure 190B connected to a lower gate structure 160A and an upper gate structure 160B, respectively.

In the semiconductor device 100, the gate structure 160 may be disposed between the bottom dielectric isolation structure 400 and the channel structure 140, between the lower channel layers 140A and the upper channel layers 140B of the channel structure 140, and on the channel structure 140. In example embodiments, the lower gate structure 160A may be disposed between the bottom dielectric isolation structure 400, and the lowermost lower channel layer among the lower channel layers 140A, between the lower channel layers 140A, and between an uppermost lower channel layer and a middle dielectric isolation structure 300 among the lower channel layers 140A. In example embodiments, the upper gate structure 160B may be disposed between the middle dielectric isolation structure 300 and the lowermost upper channel layer among the upper channel layers 140B, between the upper channel layers 140B, and on the upper channel layers 140B.

Accordingly, the semiconductor device 100 may include transistors having a multi-bridge channel FET (MBCFET™) structure, which is a gate-all-around type field effect transistor. In example embodiments, a semiconductor device may include transistors of a complementary FET (CFET) structure. example embodiments may also be applied to a transistor with a 3D-SFET (three dimensional—stacked FET) structure vertically stacking a plurality of transistors.

As illustrated in FIGS. 2 and 3, the semiconductor devices 100 and 100A according to the example embodiments may have a first transistor structure TR1 and a second transistor structure TR2 stacked in a vertical direction, for example, a Z-direction.

Referring to FIGS. 2 and 3, the semiconductor devices 100 and 100A according to the example embodiments may include a third transistor structure TR3 and a fourth transistor structure TR4 stacked in the vertical direction. The third transistor structure TR3 and the fourth transistor structure TR4 may be configured as transistor structures adjacent to each of the first transistor structure TR1 and the second transistor structure TR2 in the second direction, for example, in the Y-direction.

Each of the first, second, third, and fourth transistor structures TR1, TR2, TR3, and TR4 employed in the example embodiments may be configured as a MBCFET™ (multi-bridge channel FET) including a lower gate structure 160A extending around or surrounding the lower channel layers 140A and an upper gate structure 160B extending around or surrounding the upper channel layers 140B. Each of the first transistor structures TR1 may be configured as one of N-type MOSFET and P-type MOSFET, and the second transistor structures TR2 may be configured as one of P-type MOSFET and N-type MOSFET. In some example embodiments, the first and second transistor structures TR1 and TR2 may be configured as P-type MOSFET and N-type MOSFET, respectively. The third transistor structure TR3 and the fourth transistor structure TR4 may also have the same or similar characteristics as that of the MOSFET types of the above-described first transistor structures TR1 and second transistor structures TR2.

In the example embodiments, the first and second transistor structures TR1 and TR2 may be configured not to share a common gate electrode. For example, each of the first and second transistor structures TR1 and TR2 may be configured to be connected to different gate structures 160A and 160B. Also, by disposing the gate isolation insulating layer 170 between the first and second transistor structures TR1 and TR2, the first and second transistor structures TR1 and TR2 may be electrically insulated from each other. The third and fourth transistor structures TR3, TR4 also have the same or similar characteristics as those of the first and second transistor structures TR1 and TR2, and detailed descriptions thereof will not be provided.

Specifically, each of the first and third transistor structures TR1 and TR3 may have lower channel layers 140A spaced apart from each other in a vertical direction, for example, Z-direction, a lower gate electrode 160A_1 extending around or surrounding the lower channel layers 140A, a lower source/drain regions 150A connected to the lower channel layers 140A on one side of the lower gate electrode 160A_1, and a gate dielectric layer 162 between the lower channel layers 140A and the lower gate electrode 160A_1.

In example embodiments, at least one lower gate electrode layer may be stacked in order on a side surface and a lower surface of lower gate electrode 160A_1. In the example embodiments, the first lower gate electrode layer 160A_2 may be disposed on the side surface and the lower surface of lower gate electrode 160A_1, and the second lower gate electrode layer 160A_3 may be disposed on the first lower gate electrode layer 160A_2. The number of lower gate electrode layers disposed on the lower gate electrode 160A_1 is not limited thereto.

Referring together to FIG. 4A, a single lower gate electrode layer (or “first lower gate electrode layer 160A_2”) may be stacked on the side surface and the lower surface of lower gate electrode 160A_1.

Referring to FIG. 4B, the first lower gate electrode layer 160A_2, the second lower gate electrode layer 160A_3, and the third lower gate electrode layer 160A_4 may be stacked in order on the side surface and the lower surface of lower gate electrode 160A_1.

Referring back to FIGS. 2 and 3, each of the second and fourth transistor structures TR2 and TR4 may include upper channel layers 140B, upper gate electrode 165 extending around or surrounding upper channel layers 140B, upper source/drain regions 150B connected to upper channel layers 140B on both sides of upper gate electrode 165, and a gate dielectric layer 162 between the upper channel layers 140B and the upper gate electrode 165.

A gate isolation insulating layer 170 may be disposed between the first transistor structure TR1 and the second transistor structure TR2 spaced apart from each other in the vertical direction, for example, in the Z-direction, and between the third transistor structure TR3 and the fourth transistor structure TR4 spaced apart from each other in the vertical direction. The gate isolation insulating layer 170 may have a uniform thickness of d₂. The second thickness d₂ may be, for example, about 5 nm or more, for example, 5 nm to 15 nm, 5 nm to 13 nm, 5 nm to 10 nm, or 7 nm to 10 nm. The gate isolation insulating layer 170 may be configured to electrically insulate the first transistor structure TR1 and the second transistor structure TR2 spaced apart from each other in the vertical direction, and the third transistor structure TR3 and the fourth transistor structure TR4 spaced apart from each other in the vertical direction may be configured to be electrically insulated from each other.

Referring to FIGS. 3, the gate isolation insulating layer 170 may be in contact with a side surface of the middle dielectric isolation structure 300 on the upper surface of the lower gate structure 160A including a lower gate electrode 160A_1 and at least one lower gate electrode layer 160A_2, 160A_3, and 160A_4. The gate isolation insulating layer 170 may extend downwardly along the side surface of the lower gate structure 160A in the form of a liner on the upper surface of the lower gate structure 160A. In the lower portion of the lower gate structure 160A, the gate isolation insulating layer 170 may be in contact with at least a portion of the lower surface of the lower gate electrode layer disposed on the outermost side of the at least one lower gate electrode layer 160A_2, 160A_3, and 160A_4. In example embodiments, in the lower portion of the lower gate structure 160A, the gate isolation insulating layer 170 may be in contact with at least a portion of the upper surface of the second lower gate electrode layer 160A_3.

Referring together to FIG. 4A, in the lower portion of the lower gate structure 160A, the gate isolation insulating layer 170 may be in contact with at least a portion of the lower portion or the lower surface of the first lower gate electrode layer 160A_2. In some embodiments, a gate dielectric layer 162 is part of the middle dielectric isolation structure 300.

Referring to FIG. 4B together, in the lower portion of the lower gate structure 160A, the gate isolation insulating layer 170 may be in contact with at least a portion of the lower portion or the lower surface of the third lower gate electrode layer 160A_4.

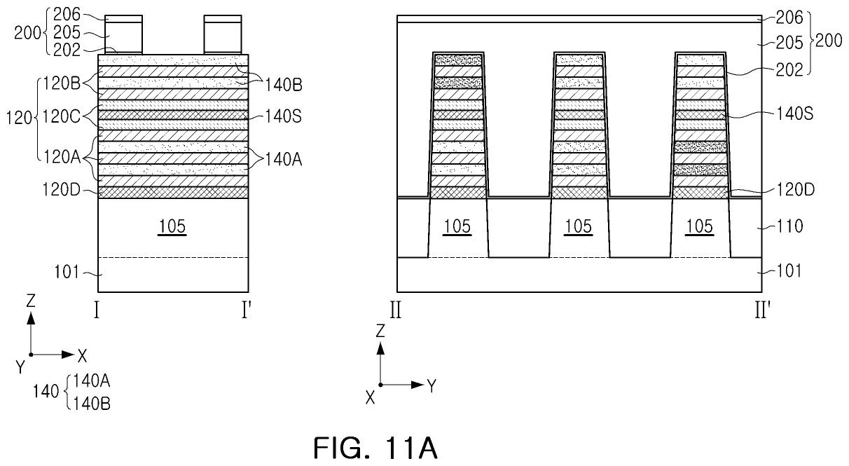

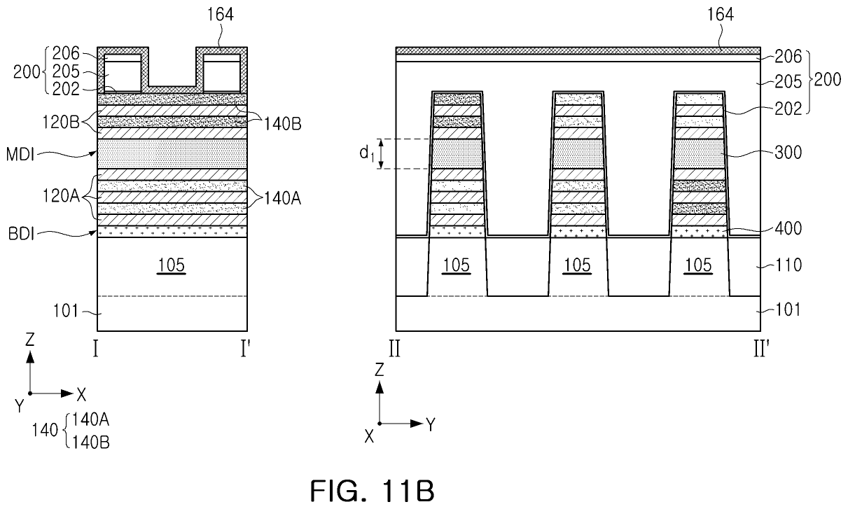

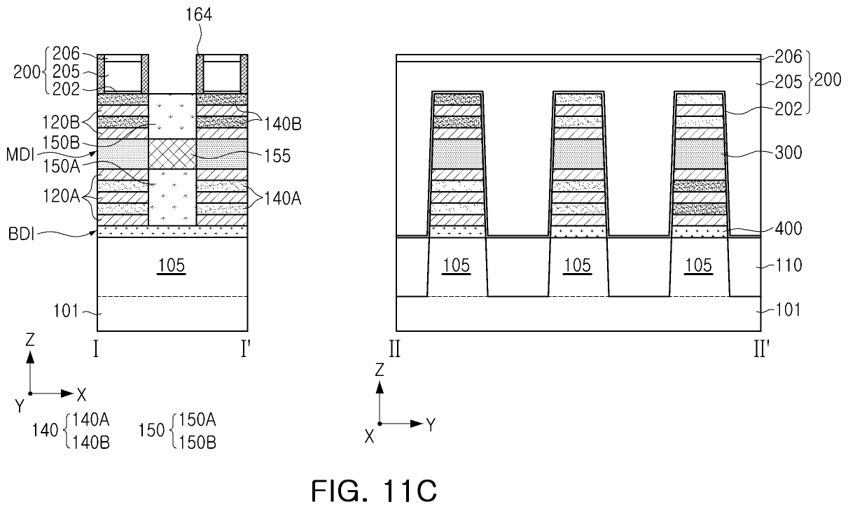

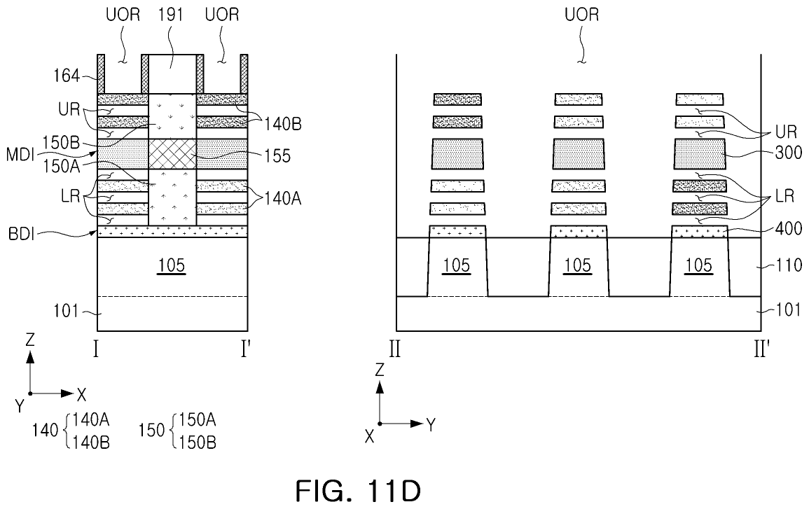

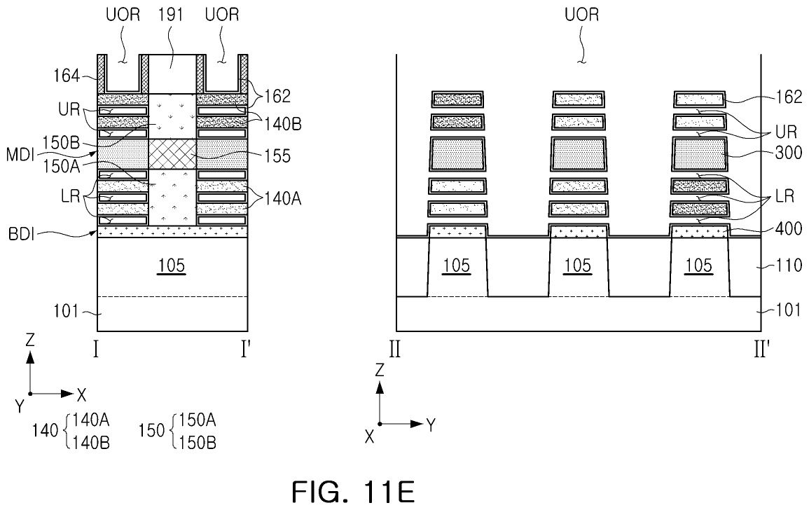

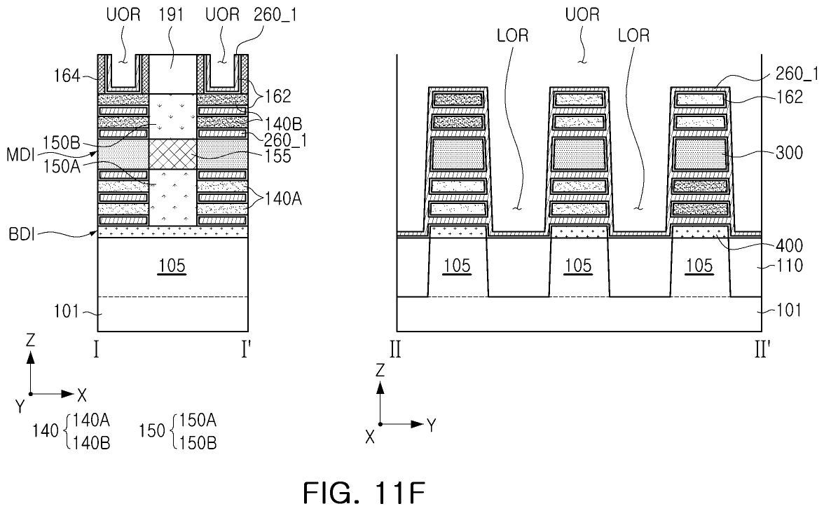

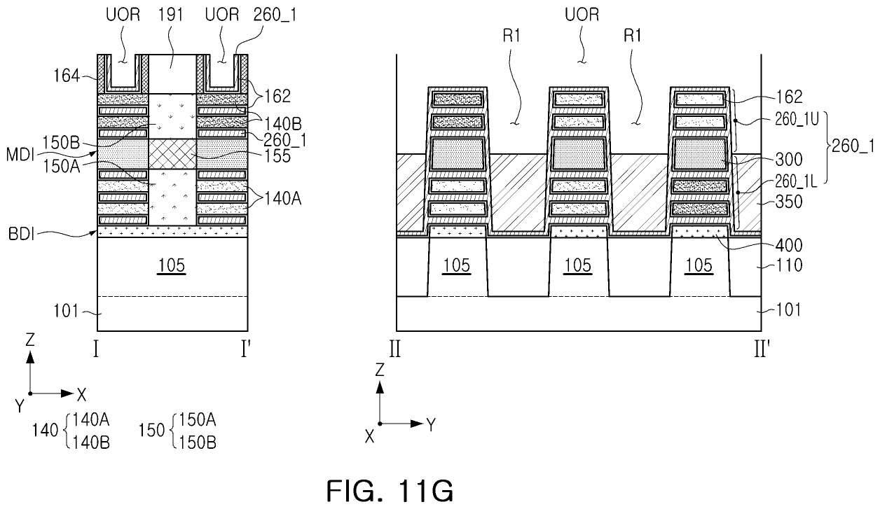

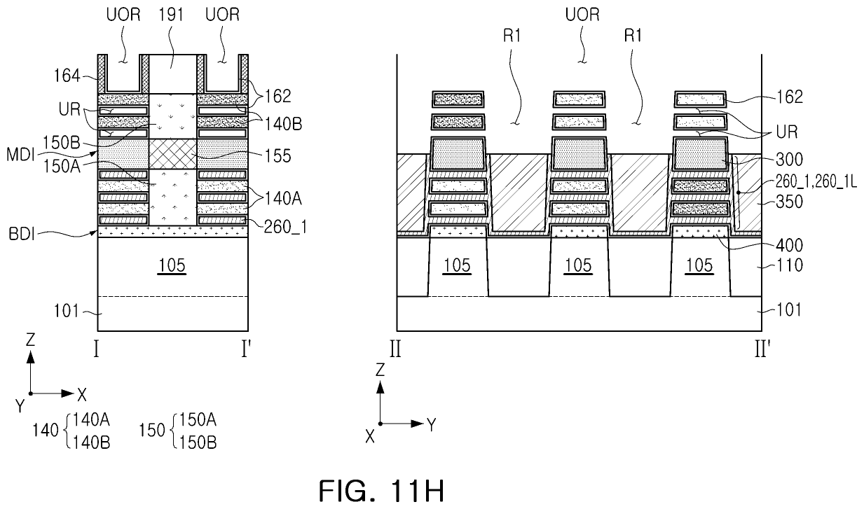

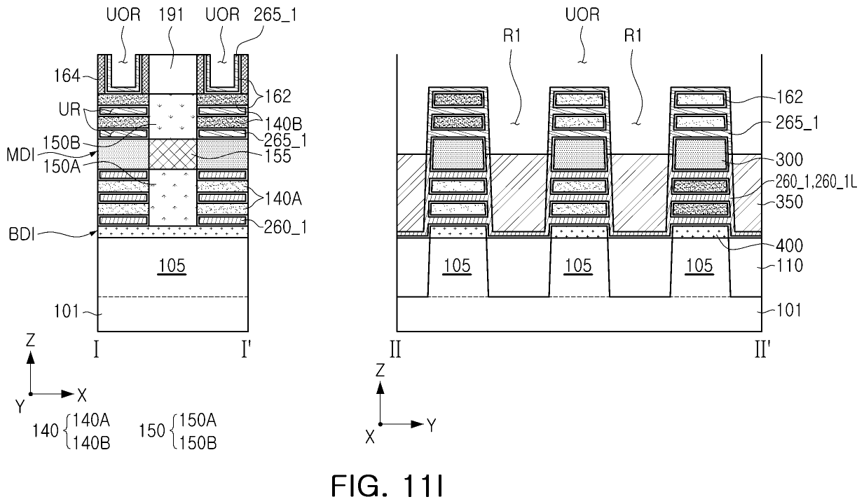

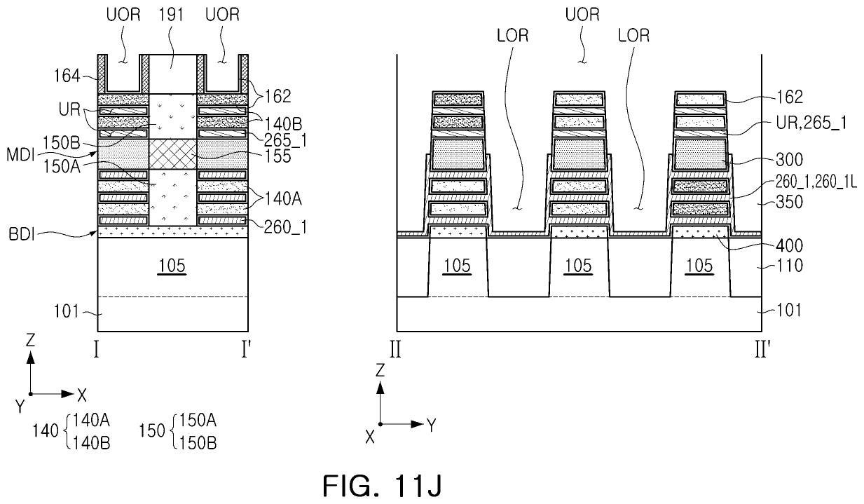

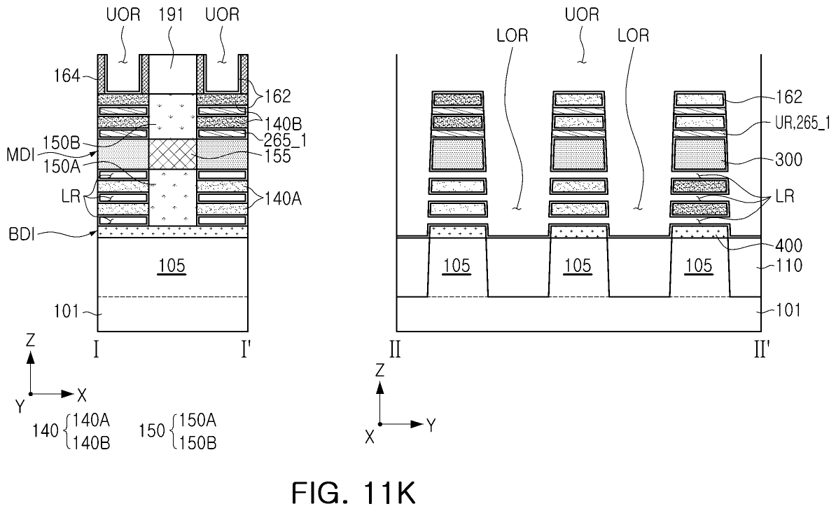

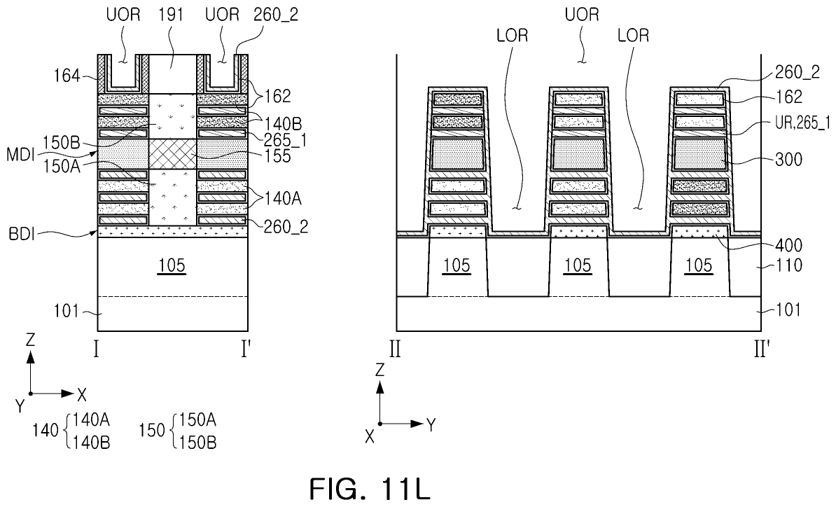

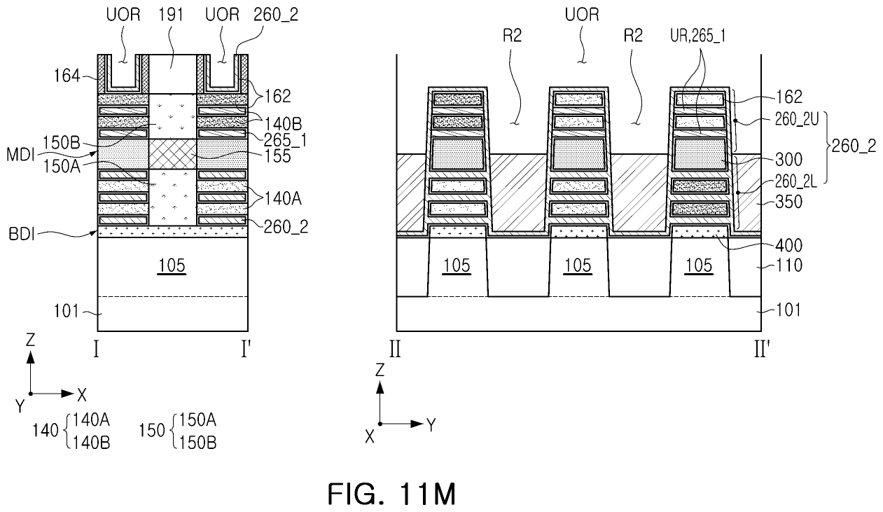

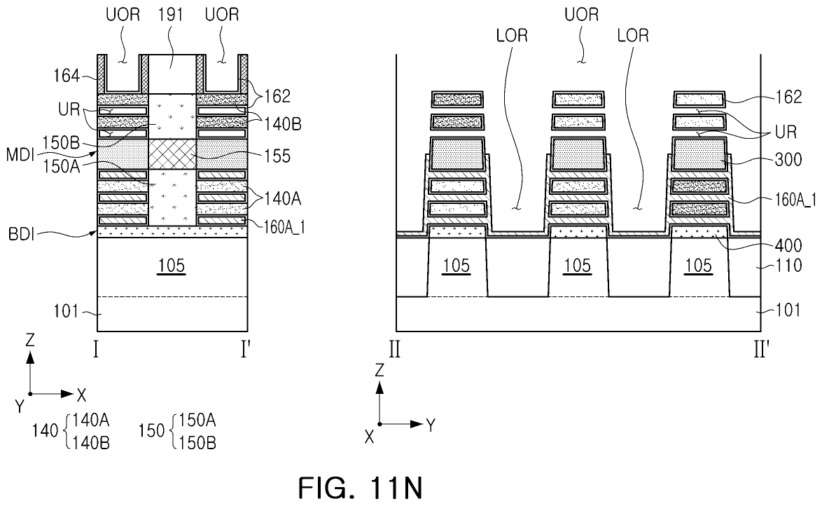

Referring to FIG. 4C, the upper surface 160A_U of the lower gate structure may have a downwardly curved shape, for example, a parabolic cross-sectional shape, curved downwardly. Referring to FIG. 11H regarding the manufacturing method, through the wet etching process, the upper surface 160A_U of the lower gate structure may have a groove portion curved downwardly, as shown in FIG. 4C.

The channel structure 140 may include a lower channel structure 140A including two or more plurality of channel layers spaced apart from each other in a direction perpendicular to the upper surface of active region 105, for example, Z-direction, such as, lower channel layers, and upper channel structure 140B including upper channel layers on the active region 105 (shown in FIG. 11A). The plurality of channel layers 140A and 140B may be connected to the source/drain regions 150 and may be spaced apart from the bottom dielectric isolation structure 400. The upper channel layers 140B may be disposed on each of the middle dielectric isolation structure 300, and may be spaced apart from each other in the Z-direction.

The plurality of channel layers 140A and 140B may have the same or similar width in the Y-direction. In example embodiments, widths of the plurality of channel layers 140A and 140B in the Y-direction may decrease in a direction perpendicular to the first surface, that is, from the first surface to the second surface. Widths of the plurality of channel layers 140A and 140B in the X-direction may decrease in a direction perpendicular to the first surface, that is, in the direction from the first surface to the second surface.

The plurality of channel layers 140A and 140B may be formed of a semiconductor material, and may include, for example, at least one of silicon (Si), silicon germanium (SiGe), and germanium (Ge). For example, the plurality of channel layers 140A and 140B may be formed of the same material as that of the substrate 101 (see FIG. 11A). The plurality of channel layers 140A and 140B may be spaced apart from each other perpendicularly to the first surface. The number and the shape of the plurality of channel layers 140A and 140B included in the channel structure 140 may vary in example embodiments.

The middle dielectric isolation structure 300 may be disposed between the uppermost lower channel layer among the lower channel layers 140A and the lowermost upper channel layer among the upper channel layers 140B. The middle dielectric isolation structure 300 may be referred to as an intermediate insulating pattern. The middle dielectric isolation structure 300 may include insulating materials, such as oxide, nitride and oxynitride. The middle dielectric isolation structure 300 may separate the lower channel layers 140A from the upper channel layers 140B. The middle dielectric isolation structure 300 may have a first thickness d₁ between the lower channel layers 140A and the upper channel layers 140B. The first thickness d₁ may be about 10 nm or more, for example, 10 nm to 100 nm, 10 nm to 80 nm, or 10 nm to 50 nm.

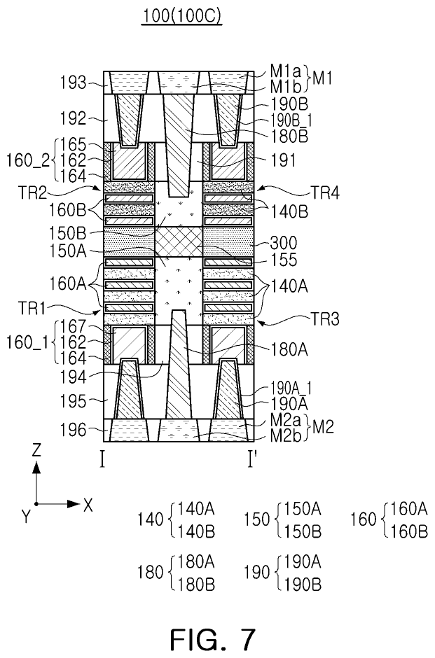

The bottom dielectric isolation structure 400 may be disposed between the lower gate structure 160A and the active region 105, but example embodiments thereof is not limited thereto. The bottom dielectric isolation structure 400 may be referred to as a bottom insulating pattern. In example embodiments, the bottom dielectric isolation structure 400 may not be disposed, and the lower channel layer 140A may be further disposed (see FIG. 7). The bottom dielectric isolation structure 400 may include substantially the same material as that of the middle dielectric isolation structure 300, but example embodiments thereof is not limited thereto.

Gate structures 160 may include the lower gate structure 160A and the upper gate structure 160B and 160_2.

The lower gate structure 160A may extend around or surround the lower channel layers 140A, respectively, and may extend in the second direction, for example, Y-direction. The upper surface of the lower gate structure 160A may be disposed on the intermediate level between the levels of the upper surface and the lower surface of the middle dielectric isolation structure 300, but example embodiments thereof is not limited thereto. For example, the upper surface of the lower gate structure 160A may be disposed between the levels of the upper surface and the lower surface of the middle dielectric isolation structure 300.

The upper gate structure 160B may extend around or surround in plan view each of the upper channel layers 140B and may extend in the second direction, for example, the Y-direction. In example embodiments, as described above, the first and second transistor structures TR1 and TR2 may not share a common gate electrode and may be configured to be connected to different gate structures 160A and 160B. Similarly, the third and fourth transistor structures TR3 and TR4 may not share a common gate electrode.

The lower gate structure 160A may include a lower gate electrode 160A_1, and at least one lower gate electrode layer 160A_2, 160A_3, and 160A_4 stacked on lower the gate electrode 160A_1. In the example embodiments, the lower gate structure 160A may extend around or surround the lower channel layers 140A, respectively, and may include a lower gate electrode 160A_1 extending in the second direction, for example, Y-direction, and a first lower gate electrode layer 160A_2 and a second lower gate electrode layer 160A_3 stacked in order on the side surface and the lower surface of lower gate electrode 160A_1. The number of the lower gate electrode layers disposed on the lower gate electrode 160A_1 may vary in example embodiments.

As described above, referring back to FIG. 4A, a single lower gate electrode layer 160A_2 may be stacked on the side surface and the lower surface of the lower gate electrode 160A_1. Similarly, referring back to FIG. 4B, the first lower gate electrode layer 160A_2, the second lower gate electrode layer 160A_3, and the third lower gate electrode layer 160A_4 may be stacked in order on the side surface and the lower surface of lower gate electrode 160A_1.

The gate structures 160 may further include a backside gate structure 160_1 disposed on the backside of the semiconductor structure. The backside gate structure 160_1 may be disposed on the lower surface of the bottom dielectric isolation structure 400 and may extend in the second direction, for example, Y-direction.

The gate dielectric layer 162 may be provided between the lower channel layers 140A and the lower gate electrode 160A_1 and also between the upper channel layers 140B and the upper gate electrode 165. The gate dielectric layer 162 may extend around or surround the perimeter of the middle dielectric isolation structure 300 and may cover or overlap the upper surface and the side surface of the lower insulating pattern or bottom dielectric isolation structure 400.

The gate structure 160 may further include gate spacer layers 164. The gate spacer layers 164 may be disposed on both sidewalls of the electrode portion extending in the second direction, for example, the Y-direction, on the uppermost upper channel layers among the upper gate electrode 165. Also, the gate spacer layers 164 may be disposed on both sidewalls of the backside gate electrode 167 extending in the second direction, for example, the Y-direction. Although not illustrated, a gate capping layer may be formed on the gate spacer layers 164, the upper gate electrode 165, the gate spacer layers 164 and the backside gate electrode 167.

The upper gate electrode 165 of upper gate structures 160B and 160_2, the lower gate electrode 160A_1 of lower gate structure 160A, at least one lower gate electrode layers 160A_2, 160A_3, and 160A_4 and the backside gate electrode 167 of backside gate structure 160_1 in the example embodiment may include a conductive material. For example, each of the upper gate electrode 165, the lower gate electrode 160A_1 and at least one lower gate electrode layers 160A_2, 160A_3, and 160A_4, and the backside gate electrode 167 may include at least one of W, Ti, Ta, Mo, TiN, TaN, WN, TiON, TiAlC, TiAlN, and/or TaAlC.

The gate electrodes 165, 160A_1, 160A_3, 160A_4, and 167 may include different conductive materials. For example, the upper gate electrode 165 of upper gate structure 160B, the lower gate electrode 160A_1 of lower gate structure 160A and at least one lower gate electrode layers 160A_2, 160A_3, and 160A_4 may be formed of a material having an appropriate work function in consideration of the desired threshold voltage. Similarly, the gate dielectric layer 162 of the upper gate structure 160B and the gate dielectric layer 162 of the lower gate structure 160A may include different dielectric layers or a combination thereof.

For example, the gate dielectric layer 162 may include oxide, nitride, or high-K material. The high-k material may refer to a dielectric material having a higher dielectric constant than that of silicon oxide (SiO₂). The high-K material may be one of, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and/or praseodymium oxide (Pr₂O₃).

For example, the gate spacer layers 164 may include at least one of silicon oxide, silicon nitride, and/or silicon oxynitride. In some example embodiments, the gate spacer layers 164 may include a multilayer structure. The gate capping layer may include, for example, silicon nitride, silicon oxynitride, silicon carbonitride, or silicon oxycarbonitride.

The source/drain region 150 may include a lower source/drain region 150A and an upper source/drain region 150B.

The lower source/drain region 150A may be disposed on the active region 105 on at least one side of the lower gate structures 160A and may be connected to the side surface of the lower channel layers 140A. The lower source/drain region 150A may be provided as a source region or a drain region of the first and third transistor structures TR1 and TR3. The lower source/drain region 150A may include epitaxial growth using both side surfaces of the lower channel layers 140A as a seed layer. Similarly, the upper source/drain region 150B may be connected to the side surface of the upper channel layers 140B on at least one side of the upper gate structures 160B and may be spaced apart from the lower source/drain region 150A in the vertical direction. The upper source/drain region 150B may work as a source region or a drain region of the second and fourth transistor structures TR2 and TR4. The upper source/drain region 150B may include epitaxial growth using both side surfaces of the upper channel layers 140B as seed layers.

The lower and upper source/drain regions 150A and 150B may include a semiconductor epitaxial such as silicon (Si). The lower and upper source/drain regions 150A, 150B may include different types and/or concentrations of impurities. For example, when the first transistor structure TR1 is configured as a P-type MOSFET, the lower source/drain regions 150A may include P-type doped silicon germanium (SiGe), and when the second transistor structure TR2 is configured as an N-type MOSFET, the upper source/drain regions 150B may include N-type doped silicon (Si).

The barrier structure 155 may be disposed between the lower source/drain region 150A and the upper source/drain region 150B. The barrier structure 155 may vertically overlap the lower source/drain region 150A and the upper source/drain region 150B. The barrier structure 155 may include an insulating material, for example, oxide, nitride, or oxynitride. The barrier structure 155 may separate the lower source/drain region 150A and the upper source/drain region 150B from each other in the vertical direction Z.

The contact structures 180 may include contact plugs and a barrier layer (not illustrated) disposed on the sidewall of the contact plugs. The contact structures 180 may extend into or penetrate through at least a portion of the plurality of interlayer insulating layers 191, 192, 194, and 195, may be in contact with the source/drain regions 150 and may apply an electrical signal to the source/drain regions 150.

The contact structure 180 may include a lower contact structure 180A (or “backside contact structure”) in contact with a lower portion of the lower source/drain regions 150A, and an upper contact structure 180B in contact with an upper portion of the upper source/drain regions 150B.

The upper contact structure 180B may be disposed to extend into or penetrate through the first upper insulating layer 191 and the second upper insulating layer 192 and to be in contact with an upper portion of the upper source/drain regions 150B.

The backside contact structure 180A may be disposed to extend into or penetrate through the first lower insulating layer 194, and the second lower insulating layer 195 and may be in contact with a lower portion of the lower source/drain regions 150A. Although not illustrated, the backside contact structure 180A may be disposed on the first lower insulating layer 194, and a via connecting the backside contact structure 180A and the second interconnection M2 disposed on the third lower insulating layer 196 may be disposed on the second lower insulating layer 195.

Contact plugs may include metal materials such as aluminum (Al), tungsten (W), or molybdenum (Mo). The barrier layer may include a metal nitride, such as titanium nitride (TiN), tantalum nitride (TaN), or tungsten nitride (WN).

The gate contact structure 190 may include an upper gate contact structure 190B. The upper gate contact structure 190B may be in contact with the upper gate electrode 165. The gate contact structure 190 may have a shape and a material similar to those of the contact structure 180, but example embodiments thereof are not limited thereto. In example embodiments, the upper gate contact structure 190B may include an upper gate contact barrier layer 190B_1.

The gate contact structure 190 may further include a lower gate contact structure 190A (or “backside gate contact structure 190A”). As described with reference to FIG. 3, the backside gate contact structure 190A may be implemented by disposing the gate isolation insulating layer 170 between a plurality of transistor structures spaced apart from each other in the vertical direction (Z-direction). In example embodiments, the lower gate contact structure 190A may include a lower gate contact barrier layer 190A_1. By implementing the backside gate contact structure 190A, the first transistor may exchange electrical signals with an external entity through the backside gate contact structure 190A.

The first interconnection M1 may include the first upper metal interconnection M1a and the second upper metal interconnection M1b, and the second interconnection M2 may include the first lower metal interconnection M2a and the second lower metal interconnection M2b. The second upper metal interconnection M1b may be electrically connected to the upper source/drain regions 150B through the upper contact structure 180B, and the first upper metal interconnection M1a may be electrically connected to the upper gate electrode 165 through the upper gate contact structure 190B. The second lower metal interconnection M2b may be electrically connected to the lower source/drain regions 150A through the lower contact structure 180A, and the first lower metal interconnection M2a may be electrically connected to the lower gate electrode 160A_1 through the lower gate contact structure 190A.

Referring to FIGS. 1, 2, and 3 together, by implementing the backside gate contact structure 190A on the backside of the semiconductor device 100, the upper and lower devices of devices adjacent to each other in the X-direction may be electrically connected to each other. In example embodiments, the first lower metal interconnection M2a connected to the first transistor structure TR1 (see FIGS. 2 and 3(a)) and the first upper metal interconnection M1a connected to the fourth transistor structure TR4 (see FIGS. 2 and 3(b)) may be electrically connected to each other in a region other than the region illustrated in the drawing. In this case, the first transistor structure TR1 and the fourth transistor structure TR4 may be cross-coupled to each other XC1 by the first lower metal interconnection M2a and the first upper metal interconnection M1a electrically connected to each other (see FIG. 1).

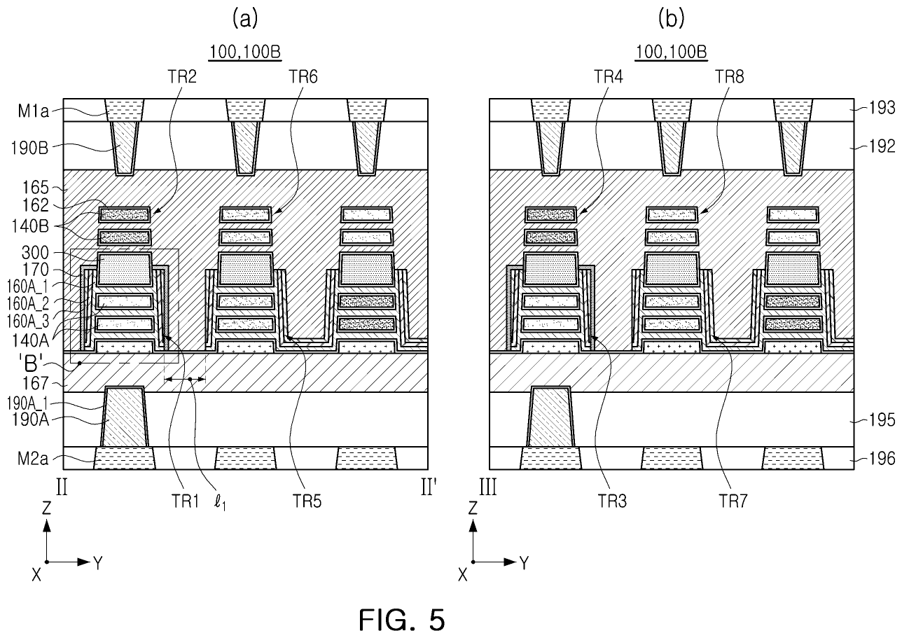

FIG. 5 is a cross-sectional diagram illustrating semiconductor devices 100 and 100B taken along lines II-II′ and III-III′ in FIG. 1.

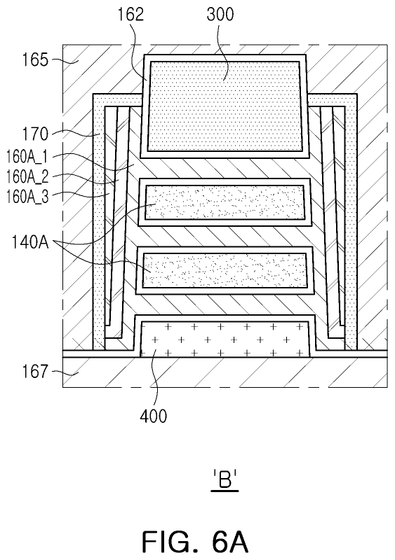

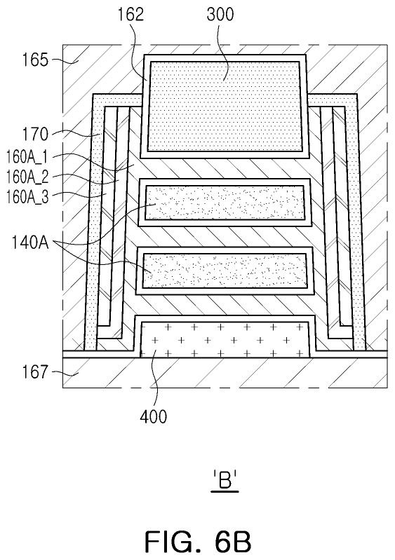

FIGS. 6A and 6B are an enlarged diagram illustrating a portion of semiconductor devices 100 and 100B according to example embodiments. FIGS. 6A and 6B illustrate region “B” in FIG. 5.

Referring to FIG. 5, the semiconductor device 100, 100B in example embodiments may be configured the same as or similarly to the examples described with reference to FIGS. 1 to 4C other than the configuration (see FIG. 5, left portion) in which the first transistor structure TR1 may be electrically isolated from the fifth transistor structure TR5 adjacent in the second direction, for example, the Y-direction, and the configuration (see FIG. 5, right portion) in which the third transistor structure TR3 may be electrically insulated from the seventh transistor structure TR7 adjacent in the second direction.

Referring to FIG. 5, the fifth transistor structure TR5 may be configured as a transistor structure adjacent to the first transistor structure TR1 in the second direction, and the sixth transistor structure TR6 may be configured as a transistor structure adjacent to the second transistor structure TR2 in the second direction. Similarly, the seventh transistor structure TR7 may be configured as a transistor structure adjacent to the third transistor structure TR3 in the second direction, and the eighth transistor structure TR8 may be configured as a transistor structure adjacent to the fourth transistor structure TR4 in the second direction. The sixth and eighth transistor structures TR6 and TR8 may be configured the same as or similar to the second and fourth transistor structures TR2 and TR4 described with reference to FIGS. 1 to 4C, and detailed descriptions thereof will thus not be provided. The fifth and seventh transistor structures TR5 and TR7 may be configured the same as or similar to the first and third transistor structures TR1 and TR3 described with reference to FIGS. 1 to 4C other than the configuration in which the fifth and seventh transistor structures TR5 and TR7 may be electrically insulated from the first and third transistor structures TR1 and TR3 adjacent in the second direction, respectively.

Referring to FIG. 5, the first and third transistor structures TR1 and TR3, respectively, may be configured such that the lower gate electrode 160A_1 extending around or surrounding the lower channel layers 140A may not extend in the second direction. In other words, the lower gate electrodes 160A_1 of the first and third transistor structures TR1 and TR3 may be configured not to be connected to the lower gate electrodes 160A_1 of the fifth and seventh transistor structures TR5 and TR7, respectively. The first transistor structure TR1 and the fifth transistor structure TR5 may be spaced apart from each other by a first distance 11 in the second direction. For example, the first distance 11 may be the distance between the side surface of the lower gate structure of the first transistor structure TR1 and the side surface of the fifth transistor structure TR5 in the second direction. The first distance 11 may be about 10 nm or more, for example, 10 nm to 20 nm, 10 nm to 15 nm, or 15 nm to 20 nm.

Referring to FIGS. 5 and 6A together, in the lower gate structure 160A, at least a portion of the side surface of the lower gate electrode 160A_1 and at least a portion of the side surface of the first lower gate electrode layer 160A_2 may be exposed in the second direction. The gate isolation insulating layer 170 may be in contact with the side surface of the middle dielectric isolation structure 300 on the upper surface of the lower gate structure 160A, and may extend along the side surface of the lower gate structure 160A in the form of a liner. In this case, the side surface of the gate isolation insulating layer 170 may be configured to be perpendicular to the first surface and second surface of the semiconductor structure, but example embodiments thereof is not limited thereto. As illustrated in FIG. 6B, the side surface of the gate isolation insulating layer 170 may extend in the downward direction of the lower gate structure 160A along the side surface of the lower gate structure 160A so as to form an oblique line with the first surface and second surface of the semiconductor structure of the substrate 101. In the lower portion of the lower gate structure 160A, the gate isolation insulating layer 170 may be in contact with the exposed side surface of the side surfaces of the lower gate electrode 160A_1 and the exposed side surface of the first lower gate electrode layer 160A_2. Accordingly, the lower gate structure 160A in the example embodiments may be electrically insulated from the upper gate structure 160B.

FIG. 7 is a cross-sectional diagram illustrating a semiconductor device 100 and 100C according to example embodiments, taken along line I-I′ in FIG. 1.

Referring to FIG. 7, the semiconductor device 100 may be similar to the example described with reference to FIGS. 1 to 6B, other than the configuration in which the middle dielectric isolation structure 300 is not disposed between the lower channel layers 140A and the upper channel layers 140B.

As illustrated in FIG. 7, the middle dielectric isolation structure 300 may not be disposed between the lower channel layers 140A and the upper channel layers 140B, and an additional lower channel layer 140A may be further disposed.

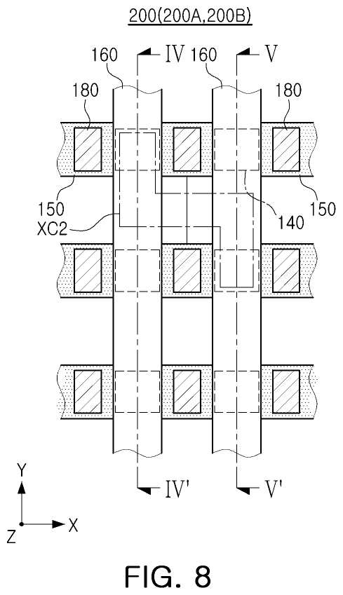

FIG. 8 is a plan diagram illustrating a semiconductor device 200, 200A, and 200B according to example embodiments.

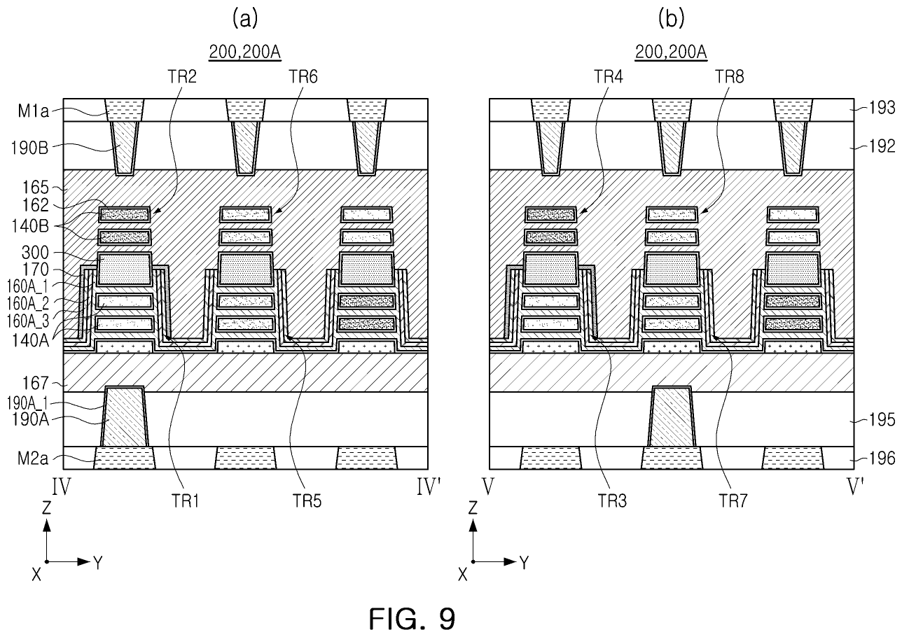

FIG. 9 is a cross-sectional diagram illustrating semiconductor devices 200 and 200A taken along lines IV-IV′ and cutting lines V-V′ in FIG. 8.

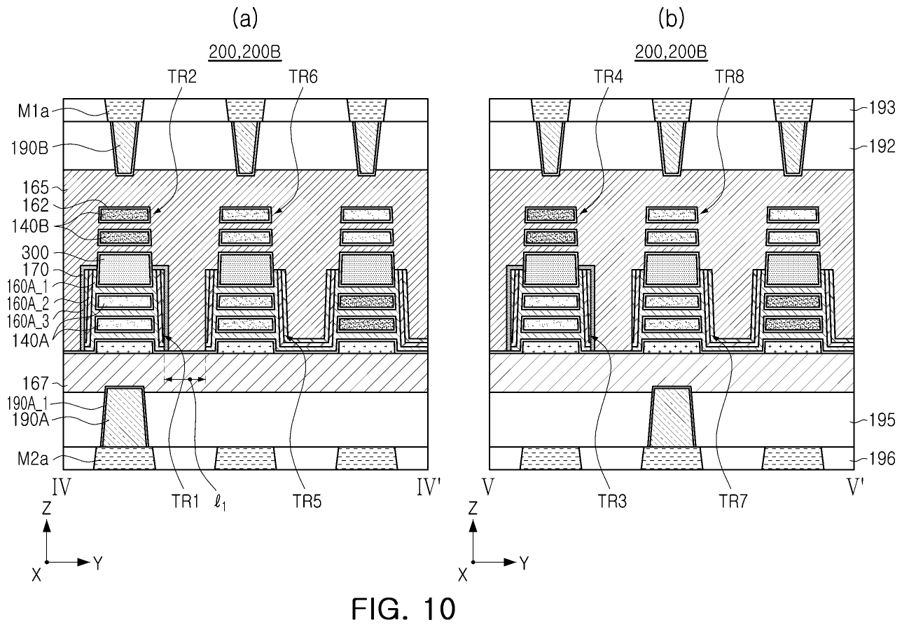

FIG. 10 is a cross-sectional diagram illustrating semiconductor devices 200 and 200B taken along lines IV-IV′ and cutting lines V-V′ in FIG. 8.

For ease of description, FIG. 8 illustrates only a portion of components of the semiconductor device.

Referring to FIG. 8, the semiconductor devices 200, 200A, and 200B in example embodiments may be configured the same as or similar to the examples described with reference to FIGS. 1 to 6B other than the configuration in which the upper and lower devices of devices adjacent to each other in the first direction (e.g., X-direction) and the second direction (e.g., Y-direction) may be electrically connected to each other.

Referring to FIG. 9, the first lower metal interconnection M2a (FIG. 9(a)) electrically connected to the first transistor structure TR1 and the first upper metal interconnection M1a (FIG. 9(b)) connected to the eighth transistor structure TR8 may be electrically connected to each other in a region other than the illustrated region. In this case, the first transistor structure TR1 and the eighth transistor structure TR8 may be cross-coupled to each other XC2 by the first lower metal interconnection M2a and the first upper metal interconnection M1a electrically connected to each other (see FIG. 8).

Referring to FIG. 10, the first and eighth transistor structures TR1 and TR8 may be configured the same as or similar to the example described with reference to FIG. 9 other than the configuration in which the lower gate electrode 160A_1 extending around or surrounding the lower channel layers 140A may be configured not to extend in the second direction.

FIGS. 11A to 11N are cross-sectional diagrams illustrating processes of a method of manufacturing a semiconductor device in order according to example embodiments.

FIGS. 11A to 11N illustrate example embodiments of a manufacturing method including patterning lower gate electrode 160A_1.

Referring to FIG. 11A, a device isolation layer 110 defining an active region 105 may be formed on the substrate 101, a sacrificial barrier layer 120D, sacrificial layers 120, lower channel layers 140A, semiconductor pattern 140S, and upper channel layers 140B may be stacked alternately, an active structure may be formed, and sacrificial gate structures 200 may be formed in the second direction Y to intersect the active structure.

The substrate 101 may have an upper surface extending in the X-direction and Y-direction. The substrate 101 may include a semiconductor material, such as a group IV semiconductor, a group III-V compound semiconductor, or a group II-VI compound semiconductor. For example, group IV semiconductors may include silicon, germanium, or silicon-germanium. The substrate 101 may be provided as a bulk wafer, an epitaxial layer, a silicon on insulator (SOI) layer, or a semiconductor on insulator (SeOI) layer.

The active region 105 may be defined by the device isolation layer 110 in the substrate 101 and may be disposed to extend in the first direction, for example, the X-direction. The active region 105 may have a structure protruding from the substrate 101. The upper end of active region 105 may be disposed to protrude from the upper surface of the device isolation layer 110 at a predetermined height. The active region 105 may be formed as a portion of the substrate 101 or may include an epitaxial layer grown from the substrate 101. The active region 105 may include impurities or may include doped regions including impurities.

The device isolation layer 110 may define the active region 105 in the substrate 101. The device isolation layer 110 may be formed, for example, by a shallow trench isolation (STI) process. In example embodiments, the device isolation layer 110 may further include a region extending deeper and having a step difference to a region below the substrate 101. The device isolation layer 110 may partially expose an upper portion of the active region 105. The device isolation layer 110 may be formed of an insulating material. The device isolation layer 110 may be, for example, oxide, nitride, or a combination thereof.

The sacrificial barrier layer 120D may be formed of a material having etch selectivity for the sacrificial layers 120, the lower channel layers 140A, the semiconductor pattern 140S, and/or the upper channel layers 140B. The sacrificial barrier layer 120D may include silicon (Si) or silicon germanium (SiGe). When the sacrificial barrier layer 120D includes silicon germanium (SiGe), the sacrificial barrier layer 120D may have etch selectivity through a difference in germanium (Ge) concentration from the sacrificial layers 120. The sacrificial barrier layer 120D may be replaced with the bottom dielectric isolation structure BDI (400) as illustrated in FIGS. 2 and 3 through a subsequent process.

The sacrificial layers 120 may include lower sacrificial layers 120A, intermediate sacrificial layers 120C, and upper sacrificial layers 120B. As illustrated in FIG. 3, through a subsequent process, the lower sacrificial layers 120A may be replaced with the gate dielectric layer 162 and the lower gate electrode 160A_1, and the upper sacrificial layers 120B may be replaced with the gate dielectric layer 162 and the upper gate electrode 165. The intermediate sacrificial layers 120C and the semiconductor pattern 140S may be replaced with the middle dielectric isolation structure 300 as illustrated in FIGS. 2 and 3 through a subsequent process.

The sacrificial layers 120 may be formed of a material having etch selectivity for the lower channel layers 140A, the semiconductor pattern 140S, and the upper channel layers 140B. The lower channel layers 140A, the semiconductor pattern 140S, and the upper channel layers 140B may include materials different from that of the sacrificial layers 120. In example embodiments, the lower channel layers 140A, the semiconductor pattern 140S, and the upper channel layers 140B may include silicon (Si), and the sacrificial layers 120 may include silicon germanium (SiGe), but example embodiments thereof is not limited thereto.

The sacrificial barrier layer 120D, the sacrificial layers 120, the lower channel layers 140A and the upper channel layers 140B may be formed by performing an epitaxial growth process using the substrate 101 as a seed. Each of the sacrificial barrier layer 120D, the sacrificial layers 120, the lower channel layers 140A, the semiconductor pattern 140S and the upper channel layers 140B may have a thickness ranging from about 1 Å to 100 nm. The number of lower channel layers 140A, the semiconductor pattern 140S and the upper channel layers 140B, which are alternately stacked with the sacrificial layers 120, may be varied in example embodiments.

Thereafter, active structures may be formed by removing a portion of the sacrificial barrier layer 120D, the sacrificial layers 120, the lower channel layers 140A, the semiconductor pattern 140S, the upper channel layers 140B and the substrate 101, and sacrificial gate structures 200 may be formed on the active structures.

The active structure may include sacrificial barrier layers 120D, sacrificial layers 120, lower channel layers 140A, semiconductor pattern 140S, and upper channel layers 140B, which are alternately stacked with each other, and may further include an active region 105 formed by removing a portion of substrate 101 and protruding onto the upper surface of substrate 101. The active structures may be formed in the form of lines extending in one direction, for example, the X-direction, and may be spaced apart from each other in the Y-direction.

The device isolation layer 110 may be formed by filling an insulating material in the region from which a portion of the substrate 101 is removed and recessing the active region 105 to protrude. The upper surface of device isolation layer 110 may be formed on a level lower than a level of the upper surface of active region 105.

The sacrificial gate structures 200 may be configured as a sacrificial structure formed in a region in which the gate dielectric layer 162 and the upper gate electrode 165 are disposed in an upper portion of the channel structure 140, as illustrated in FIGS. 2 and 3 through a subsequent process. The sacrificial gate structures 200 may include first and second sacrificial layers 202 and 205, and a mask pattern layer 206 which may be stacked in order. The first and second sacrificial layers 202 and 205 may be patterned using the mask pattern layer 206. The first and second sacrificial layers 202 and 205 may be configured as an insulating layer and a conductive layer, respectively. For example, the first sacrificial layer 202 may include silicon oxide, and the second sacrificial layer 205 may include polysilicon. The mask pattern layer 206 may include silicon nitride. The sacrificial gate structures 200 may have a line shape intersecting the active structures and extending in one direction. For example, the sacrificial gate structures 200 may extend in the Y-direction and may be spaced apart from each other in the X-direction.

For convenience of understanding, in FIGS. 11B to 11N, middle dielectric isolation structures 300 of each of the FIGS. 2 and 3 may be described separately. For example, the middle dielectric isolation structure MDI of the left half of each of the FIGS. 11B to 11N may correspond to the middle dielectric isolation structure 300 of FIG. 2, and the bottom dielectric isolation structure BDI of the left half of each of the FIGS. 11B to 11N may correspond to the middle dielectric isolation structure 400 of FIG. 2. Likewise, the intermediate insulating pattern 300 of the right half of each of the FIGS. 11B to 11N may correspond to the middle dielectric isolation structure 300 of FIG. 3.

Referring to FIG. 11B, the middle dielectric isolation structure MDI and the bottom dielectric isolation structure BDI may be formed, and the gate spacer layers 164 may be formed to cover or overlap the upper surface and the side surface of the sacrificial gate structure 200 and the active structures.

The intermediate sacrificial layers 120C and the semiconductor pattern 140S may have etch selectivity for the sacrificial barrier layer 120D, the lower sacrificial layers 120A, upper sacrificial layers 120B, the lower channel layers 140A, and the upper channel layers 140B, such that the intermediate sacrificial layers 120C and the semiconductor pattern 140S may be selectively removed. By filling the region from which the intermediate sacrificial layers 120C and the semiconductor pattern 140S are removed with an insulating material, a middle dielectric isolation structure MDI and am intermediate insulating pattern 300 may be formed. The middle dielectric isolation structure MDI and intermediate insulating pattern 300 may include, for example, oxide or nitride.

Since the sacrificial barrier layer 120D may have etch selectivity for the sacrificial layers 120, the lower channel layers 140A, and the upper channel layers 140B, the sacrificial barrier layer 120D may be selectively removed. A bottom dielectric isolation structure BDI may be formed by filling an insulating material in the region from which the sacrificial barrier layer 120D is removed. The bottom dielectric isolation structure BDI may include, for example, oxide or nitride. Here, not being limited to the above process, the middle dielectric isolation structure MDI and the bottom dielectric isolation structure BDI may be formed simultaneously by simultaneously removing the sacrificial barrier layer 120D, the intermediate sacrificial layers 120B, and the semiconductor pattern 140S and filling therein with an insulating material.

The gate spacer layers 164 may be formed to cover or overlap both sidewalls and upper surfaces of the sacrificial gate structures 200. The gate spacer layers 164 may form a film having a substantially uniform thickness along the upper surface and the side surface of the sacrificial gate structures 200 and the active structures. The gate spacer layers 164 may be formed of a low dielectric constant material and, for example, may include at least one of SiO, SiN, SiCN, SiOC, SiON, and/or SiOCN.

Referring to FIG. 11C, a portion of the gate spacer layers 164 may be removed, a recess region may be formed, and a lower source/drain region 150A, a barrier structure or barrier layer 155, and an upper source/drain region 150B may be formed in order in the recess region.

A portion of gate spacer layers 164 may be removed by anisotropic etching. Accordingly, the upper surface of the sacrificial gate structures 200, and the gate spacer layers 164 present on the upper surface of the active structure may be removed.

Between the sacrificial gate structures 200, a recess region may be formed by removing a portion of the exposed upper sacrificial layers 120B, the upper channel layers 140B, the middle dielectric isolation structure MDI, the lower sacrificial layers 120A, and the lower channel layers 140A.

By forming an epitaxial layer in the recess region, the lower source/drain region 150A may be formed. The lower source/drain region 150A may be formed by epitaxial growth and may extend to be in contact with the lower channel layers 140A and the lower sacrificial layers 120A in the recess region. A barrier structure or barrier layer 155 may be formed to cover or overlap the upper surface of the lower source/drain region 150A. Thereafter, an upper source/drain region 150B may be formed on the barrier structure or barrier layer 155 and the middle dielectric isolation structure MDI to fill the remaining recess region. The upper source/drain region 150B may be formed by epitaxial growth and may extend to be in contact with the upper channel layers 140B and the upper sacrificial layers 120B in the recess region.

Referring to FIG. 11D, the first upper insulating layer 191 may be formed, and the sacrificial gate structures 200, the upper sacrificial layers 120B, and the lower sacrificial layers 120A may be removed.

The first upper insulating layer 191 may be formed by forming an insulating film covering or overlapping the sacrificial gate structures 200 and the source/drain regions 150 and performing a planarization process.

The sacrificial gate structures 200, the upper sacrificial layers 120B, and the lower sacrificial layers 120A may be selectively removed for the gate spacer layers 164, the first upper insulating layer 191, the lower channel layers 140A, the upper channel layers 140B, and the middle dielectric isolation structure MDI. First, upper open regions UOR may be formed by removing the sacrificial gate structures 200, upper gap regions UR may be formed by removing the upper sacrificial layers 120B exposed through the upper open regions UOR, and lower gap regions LR may be formed by removing the exposed lower sacrificial layers 120A. For example, when the lower sacrificial layers 120A and the upper sacrificial layers 120B include silicon germanium (SiGe) and the lower channel layers 140A and the upper channel layers 140B include silicon (Si), the lower sacrificial layers 120A and the upper sacrificial layers 120B may be selectively removed by performing a wet etching process using peracetic acid and/or a solution used in the standard clean-1 (SC1) cleaning process (NH₄OH:H₂O₂:H₂O=1:1:5) as an etchant.

Referring to FIG. 11E, a gate dielectric layer 162 may be formed in the upper open regions UOR, the upper gap regions UR, and the lower gap regions LR.

The gate dielectric layer 162 may be formed to conformally cover or overlap the internal surfaces of the upper open regions UOR, the upper gap regions UR, and the lower gap regions LR.

Referring to FIG. 11F, the first sacrificial gate layer 260_1 covering or overlapping the surface of the gate dielectric layer 162 may be formed.

Referring to FIG. 11E together with FIG. 11F, the first sacrificial gate layer 260_1 may cover or overlap the surface of the gate dielectric layer 162 formed on the channel structure 140 and intermediate insulating pattern 300 by filling a portion of the upper open regions UOR, the upper gap regions UR and the lower gap regions LR. Here, between the first sacrificial gate layers 260_1, the lower open region LORs spaced apart from each other in the first direction, for example, Y-direction, may be formed.

The first sacrificial gate layer 260_1 may include a metal material such as W, Ti, Ta, Mo, TiAlC, or TaAlC, a metal oxide such as AlO and LaO, a metal nitride such as TiN, TaN, WN, or TiAlN, a metal oxynitride such as TiON, and/or an insulating material such as SiOx.

Referring to FIG. 11G, a gap-fill layer 350 may be formed by filling the lower open region LOR and the upper open region UOR with a gap-fill material to cover or overlap the surface of the first sacrificial gate layer 260_1. A portion of the gap-fill layer 350 may be recessed to form a first recess region R1.

As the first recess region R1 is formed, the upper surface of the recessed gap-fill layer 350 may be formed between the levels of the upper surface and lower surface of the intermediate insulating pattern 300. For example, the level of the upper surface of the recessed gap-fill layer 350 may be formed in a center of the levels of the upper surface and the lower surface of the intermediate insulating pattern 300.

In the first recess region R1, an upper portion of the intermediate insulating pattern 300 of the first sacrificial gate layer 260_1, and a portion extending around or surrounding the upper channel layers 140B (or “an upper portion 260_1U of the first sacrificial gate layer”) may be exposed.

The gap-fill layer 350 may include a carbon-based gap-fill material such as an amorphous carbon film.

Referring to FIG. 11H, the exposed upper portion of the first sacrificial gate layer 260_1U may be removed through a first wet etching process in the first recess region R1. By the wet process, at least a portion of the gate dielectric layer 162 may be exposed. In example embodiments, an upper portion of the intermediate insulating pattern 300 of the gate dielectric layer 162 and a portion covering or overlapping the surface of the upper channel layers 140B may be exposed. Accordingly, an upper gap regions UR between the upper channel layers 140B may be re-exposed.

By the first wet etching process, a portion (or “lower portion 260_1L of the first sacrificial gate layer”) extending around or surrounding the lower portion of the intermediate insulating pattern 300 of the first sacrificial gate layer 260_1 and the lower channel layers 140A may remain. Here, the upper surface of the first sacrificial gate layer lower portion 260_1L may be exposed, and the exposed upper surface may have a cross-section curved downwardly by the wet process (not illustrated).

Referring to FIG. 11I, a first blocking layer 265_1 covering or overlapping the surface of the gate dielectric layer 162 exposed by the first wet etching process and blocking the upper gap regions UR may be formed.

Referring to FIG. 11H, the first blocking layer 265_1 may be formed to extend around or surround the upper channel layers 140B and the gate dielectric layer 162 in the upper gap regions UR.

The first blocking layer 265_1 may include a material similar to that of the first sacrificial gate layer 260_1. For example, the first blocking layer 265_1 may include a metal material such as W, Ti, Ta, Mo, TiAlC, or TaAlC, a metal oxide such as AlO and LaO, a metal nitride such as TiN, TaN, WN, or TiAlN, a metal oxynitride such as TiON, and/or an insulating material such as SiOx.

In the example embodiments, the first blocking layer 265_1 may include a material different from that of the first sacrificial gate layer 260_1 so as to have etch selectivity with respect to the first sacrificial gate layer 260_1. For example, when the first sacrificial gate layer 260_1 includes a metal material such as W or Ti, the first blocking layer 265_1 may include a metal oxide such as AlO or LaO, but example embodiments thereof is not limited thereto.

Referring to FIG. 11J, portions of the first blocking layer 265_1 other than the portion formed in the upper gap regions UR may be etched by a second wet etching process. Thereafter, the remaining portion of the gap-fill layer 350 may be removed.

By the second wet etching process, a portion formed on the upper surface of the intermediate insulating pattern 300 of the first blocking layer 265_1, the side surface of the upper channel layers 140B, and the upper surface of the uppermost upper channel layer among the upper channel layers may be removed.

As the remaining portion of the gap-fill layer 350 is removed, the lower open regions LOR may be formed again, and the lower portion 260_1L of the first sacrificial gate layer may be exposed by the lower open regions LOR.

Referring to FIG. 11K, the lower portion 260_1L of the first sacrificial gate layer may be removed by the third wet etching process through the lower open regions LOR.

As described with reference to FIG. 11I, the first blocking layer 265_1 and the first sacrificial gate layer 260_1 may have etch selectivity for each other, such that the first sacrificial gate layer 260_1 may be selectively removed by the third wet etching process. As the lower portion 260_1L of the first sacrificial gate layer is removed, the lower gap regions LR may be formed again, and only the first blocking layer 265_1 in the upper gap regions UR may remain.

Referring to FIG. 11L, a second sacrificial gate layer 260_2 covering or overlapping the surface of the gate dielectric layer 162 may be formed.

The second sacrificial gate layer 260_2 may at least partially or fully fill the lower gap regions LR and may extend around or surround the surface of the lower channel layers 140A, and may allow the intermediate insulating pattern 300 to extend around or surround the side surface, the side surface of the first blocking layer 265_1 in the upper gap regions UR, and the surface of the upper channel layers 140B.

The second sacrificial gate layer 260_2 may include a metallic material. For example, the second sacrificial gate layer 260_2 may include at least one of a metal material such as W, Ti, Ta, Mo, TiAlC, or TaAlC, and a metal nitride such as TiN, TaN, WN, or TiAlN.

Referring to FIG. 11M, similarly to the process in FIG. 11G, a gap-fill layer 350 covering or overlapping the second sacrificial gate layer 260_2 may be formed. A portion of the gap-fill layer 350 may be recessed and may form a second recess region R2.

In the second recess region R2, an upper portion of the intermediate insulating pattern 300 of the second sacrificial gate layer 260_2, the first blocking layer 265_1 in the upper gap regions UR, and a portion extending around or surrounding the upper channel layers 140B (or “an upper portion 260_2U of the second sacrificial gate layer”) may be exposed.

Referring to FIG. 11N, an upper portion 260_2U of the second sacrificial gate layer, and the first blocking layer 265_1 in the upper gap regions UR may be removed by the fourth wet etching process, and the remaining portion of the gap-fill layer 350 may be removed.

Referring to FIG. 11M, an upper portion 260_2U of the second sacrificial gate layer and the first blocking layer 265_1 in the upper gap regions UR may be sequentially etched from the partially recessed gap-fill layer 350 by the fourth wet etching process. However, in example embodiments, an upper portion 260_2U of the second sacrificial gate layer and the first blocking layer 265_1 in the upper gap regions UR may be removed simultaneously. In this case, an upper portion gap regions UR between the upper channel layers 140B may be formed again.

Thereafter, the remaining portion of the gap-fill layer 350 may be removed, and a lower gate electrode 160A_1 extending around or surrounding the lower channel layers 140A and in contact with at least a portion of the side surface of the intermediate insulating pattern 300 may be formed.

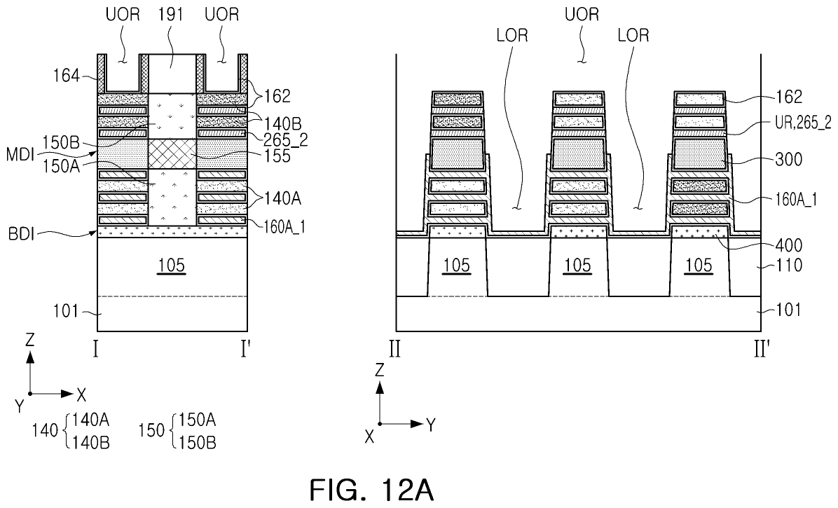

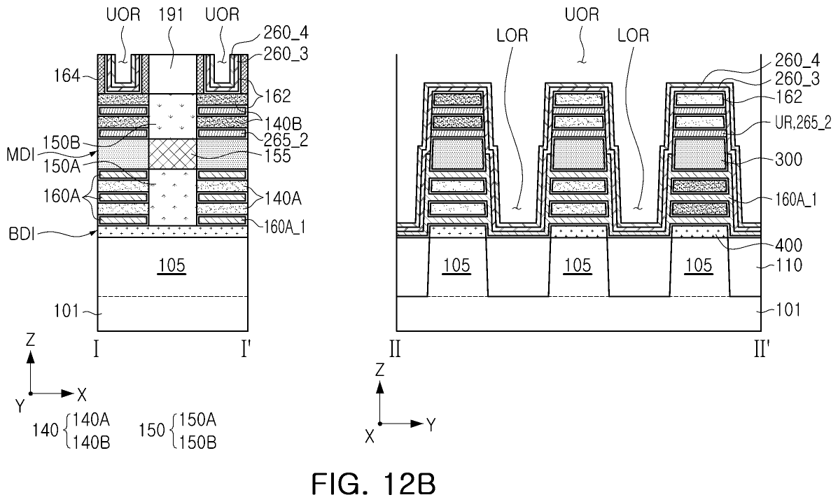

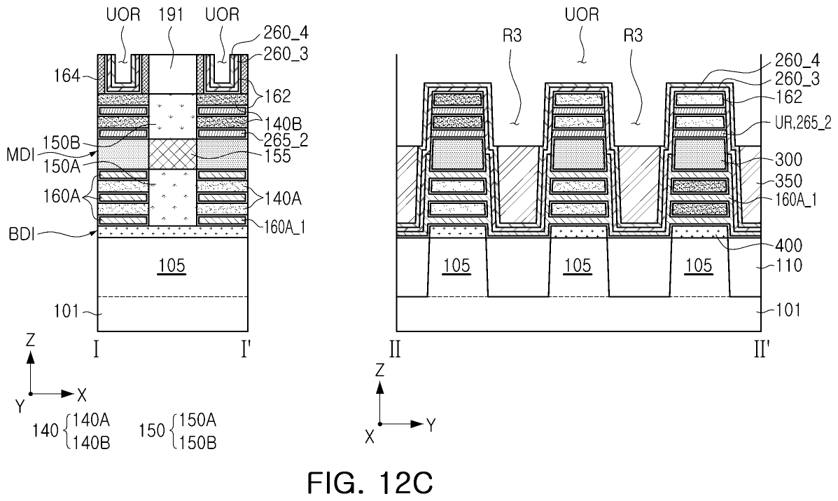

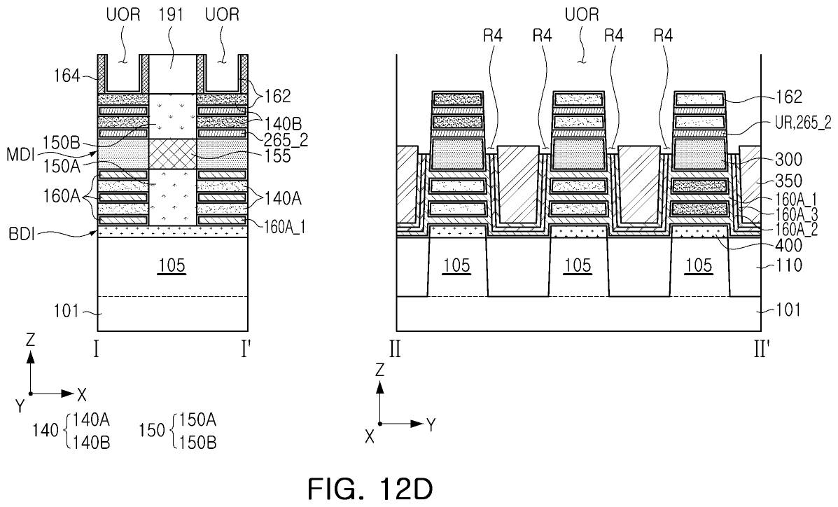

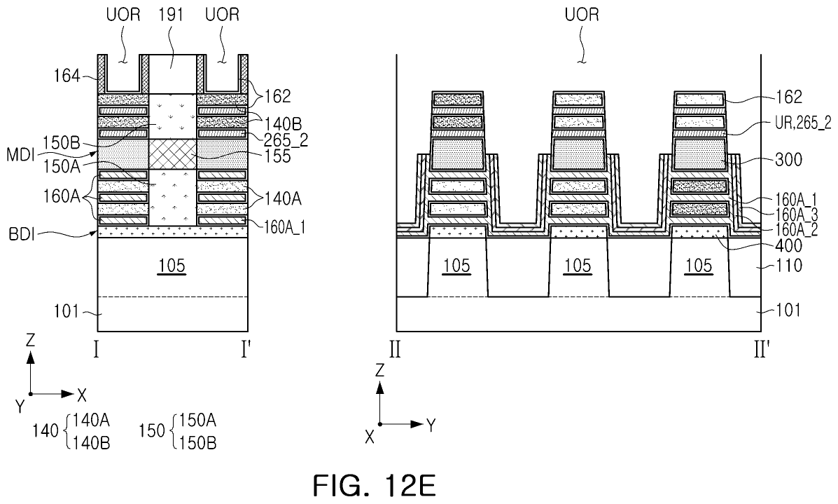

FIGS. 12A to 12E are cross-sectional diagrams illustrating processes of a method of manufacturing semiconductor devices 100 and 200 in order according to example embodiments.

FIGS. 12A to 12E illustrate an example of a method of manufacturing the lower gate structure 160A by forming a plurality of lower gate electrode layers 160A_2 and 160A_3 on the lower gate electrode 160A_1 manufactured according to FIGS. 11A to 11N.

Referring to FIG. 12A, a second blocking layer 265_2 covering or overlapping the surface of the lower gate electrode 160A_1 and the gate dielectric layer 162 may be formed. Thereafter, a portion of the second blocking layer 265_2 may be removed by a fifth wet etching process.

The second blocking layer 265_2 may be formed to cover or overlap the surface of the lower gate electrode 160A_1 and the gate dielectric layer 162 and to fill the upper gap regions UR.

Thereafter, by the fifth wet etching process, the second blocking layer 265_2 may have etch selectivity with respect to the lower gate electrode 160A_1, such that a portion covering the surface of the and gate dielectric layer 162 of the lower gate electrode 160A_1 may be selectively removed, and only the second blocking layer 265_2 in the upper gap regions UR may remain.

The second blocking layer 265_2 may include a material the same as or similar to that of the first blocking layer 265_1. For example, the second blocking layer 265_2 may include a metal material such as W, Ti, Ta, Mo, TiAlC, or TaAlC, a metal oxide such as AlO and LaO, a metal nitride such as TiN, TaN, WN, or TiAlN, a metal oxynitride such as TiON, and/or an insulating material such as SiOx.

In the example embodiments, the second blocking layer 265_2 may include a material different from the material of the lower gate electrode 160A_1 (or “second sacrificial gate layer 260_2”) described with reference to FIG. 11L to have etch selectivity for the lower gate electrode 160A_1. For example, when the lower gate electrode 160A_1 includes a metal material such as W or Ti, the second blocking layer 265_2 may include a metal oxide such as AlO or LaO, but example embodiments thereof are not limited thereto.

Referring to FIG. 12B, after the process in FIG. 12A, at least one or more sacrificial gate layers may be formed in order. In example embodiments, after the process in FIG. 12A, the third and fourth sacrificial gate layers 260_3 and 260_4 may be formed in order.

The third and fourth sacrificial gate layers 260_3 and 260_4 may include a material different from the material of the lower gate electrode 160A_1 (or “second sacrificial gate layer 260_2”) described with reference to FIG. 11L, and the third and fourth sacrificial gate layers 260_3 and 260_4 may include different materials. For example, the third and fourth sacrificial gate layers 260_3 and 260_4 may include a material having an appropriate work function in consideration of the desired threshold voltage.

Referring to FIG. 12C, a gap-fill layer 350 may be formed covering the surface of the fourth sacrificial gate layer 260_4. A portion of the gap-fill layer 350 may be recessed to form a third recess region R3.

The lower surface of the third recess region R3 may be formed in a position higher than the level of the lower surface of the first recess region R1 described with reference to FIG. 11G and the level of the lower surface of the second recess region R2 described with reference to FIG. 11M.

Referring to FIG. 12D, a portion of the third and fourth sacrificial gate layers 260_3 and 260_4 disposed in the third recess region R3 may be removed by a sixth wet etching process. By the sixth wet etching process, a fourth recess region R4 may be formed between the intermediate insulating pattern 300 and the gap-fill layer 350.

By the sixth wet etching process, the first lower gate electrode layer 160A_2 and the second lower gate electrode layer 160A_3, which are disposed in order on the side surface and the lower surface of the lower gate electrode 160A_1, may be formed.

An intermediate insulating pattern 300 and a gap-fill layer 350 may be disposed on the side surface of the fourth recess region R4, and the lower surface of the fourth recess region R4 may be in contact with the lower gate electrode 160A_1, and the plurality of lower gate electrode layers 160A_2 and 160A_3.

By the sixth wet etching process, the lower surface of the fourth recess region R4 may have a groove portion recessed downwardly. For example, the lower surface of the fourth recess region R4 may have a parabolic cross-section curved downwardly.

Referring to FIG. 12E, after the process in FIG. 12D, the remaining portion of the remaining gap-fill layer 350 may be removed, and the lower gate structure 160A may be formed.

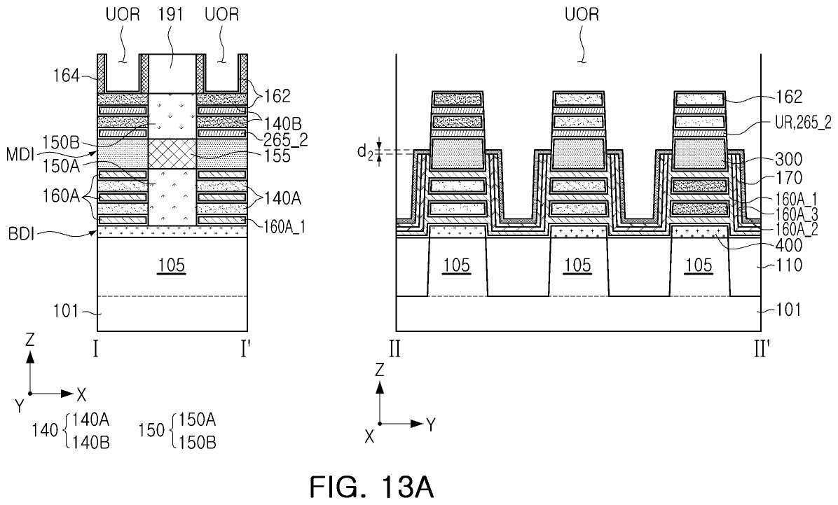

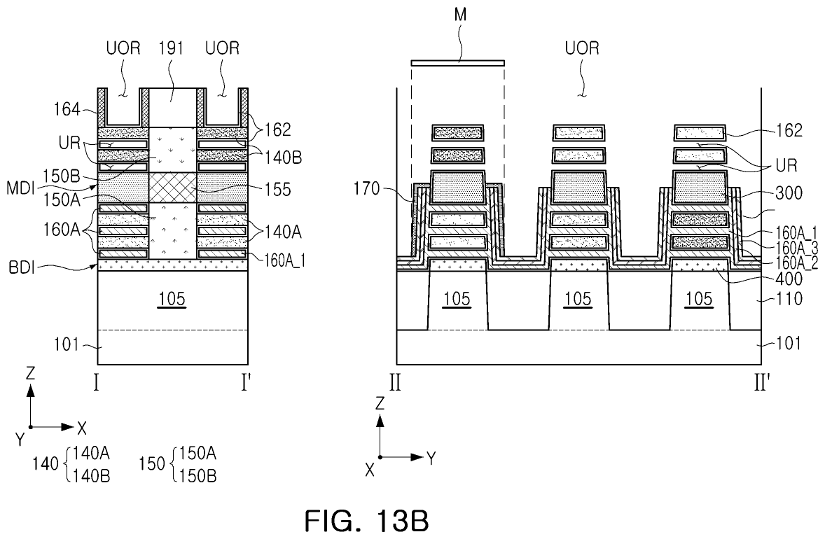

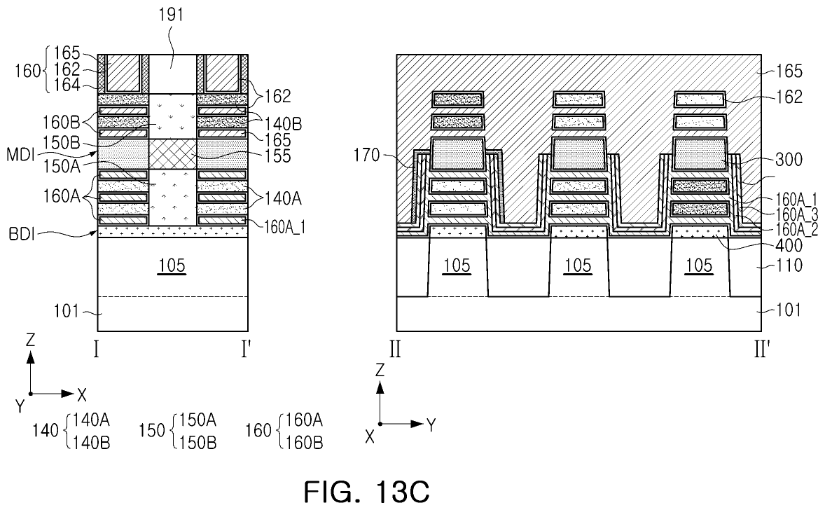

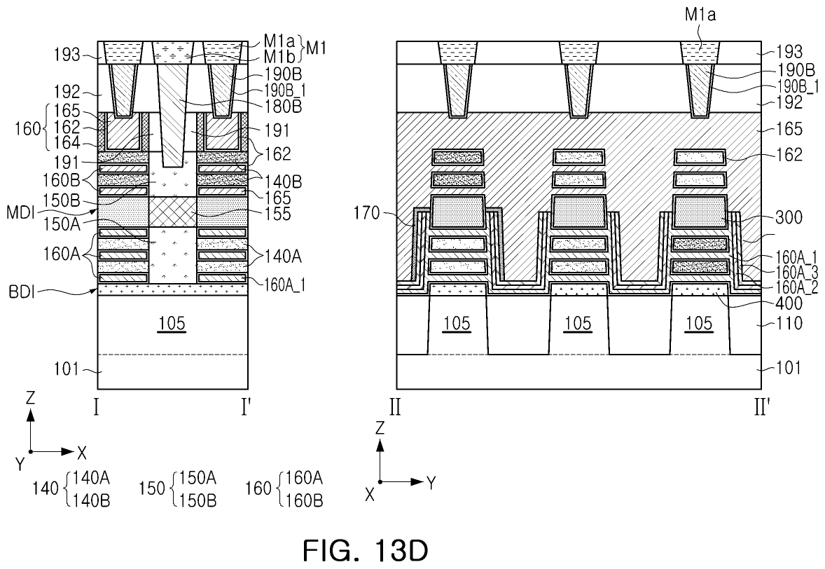

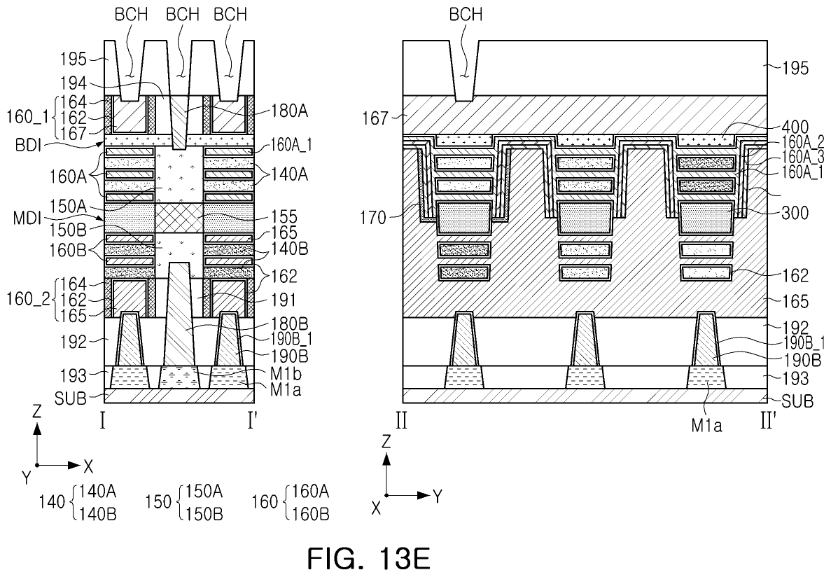

FIGS. 13A to 13E are cross-sectional diagrams illustrating processes of a method of manufacturing a semiconductor device in order according to example embodiments.

FIGS. 13A to 13E illustrate a manufacturing method for manufacturing semiconductor devices 100A and 200A by forming a gate isolation insulating layer 170 and an upper gate structure 160B on the lower gate structure 160A manufactured according to FIGS. 12A to 12E.

Referring to FIG. 13A, a gate isolation insulating layer 170 covering or overlapping the lower gate electrode 160A_1 and the surfaces of the plurality of lower gate electrode layers 160A_2 and 160A_3 may be formed.

The gate isolation insulating layer 170 may be conformally formed on the lower gate electrode 160A_1 and the surfaces of the plurality of lower gate electrode layers 160A_2 and 160A_3. The gate isolation insulating layer 170 may extend in the second direction, for example, Y-direction. The gate isolation insulating layer 170 may be formed, for example, by atomic layer deposition (ALD).

Referring to FIG. 13B, the second blocking layer 265_2 in the upper gap region UR may be removed. Thereafter, by forming the mask pattern M on the predetermined channel structure 140, the gate isolation insulating layer 170 may remain only on the predetermined lower transistor.

The gate isolation insulating layer 170 may include an insulating material. For example, the gate isolation insulating layer 170 may include at least one insulating material such as SiOx, SiN, SiOCN, or SiCN.

Since the second blocking layer 265_2 in the upper gap region UR has etch selectivity with respect to the gate isolation insulating layer 170, the second blocking layer 265_2 may be selectively removed. In this case, the upper gap region UR may be formed again.

A mask pattern M may be formed on the channel structure 140 on a lower transistor on which the gate isolation insulating layer 170 may remain. The gate isolation insulating layer 170 portion formed in a portion other than the portion in which the mask pattern M is not formed may be etched by an etching process.

Referring to FIG. 13C, a gate structure 160 may be formed in the upper gap regions UR.

The upper gate electrode 165 may be formed to fill the upper gap regions UR. Accordingly, a gate structure 160 including a gate dielectric layer 162, a gate electrode 165, and gate spacer layers 164 may be formed.

Referring to FIG. 13D, a contact structure 180B, a gate contact structure 190B, and a first interconnection M1 may be formed.

A second upper insulating layer 192 may be formed to cover or overlap the gate structure 160, a contact hole connected to the source/drain regions 150 and the upper gate electrode 165 may be formed in the second upper insulating layer 192, and a barrier layer (not illustrated) and a plug conductive layer may be formed in order such that the contact hole may be at least partially or fully filled.

A third upper insulating layer 193 may be formed to cover or overlap the contact structure 180B and the gate contact structure 190B, and a first interconnection M1 may be formed by patterning the third upper insulating layer 193 and filling a conductive material.

Although not illustrated, an interlayer insulating layer may be further formed between the second upper insulating layer 192 and the third upper insulating layer 193, thereby forming a via connecting the contact structure 180 to the first interconnection M1.

Referring to FIG. 13E, the entire structure according to FIG. 13D may be attached to the carrier substrate SUB, and the backside gate structure 160_1 and the contact structure 180A may be formed. Thereafter, a backside contact hole BCH may be formed.

The carrier substrate SUB may be attached to the third upper insulating layer 193 or the first interconnection M1 to perform a process on the lower surface of substrate 101 in FIG. 13D. In FIG. 13E, the entire structure may be illustrated rotated or inverted in a mirror image of the structure illustrated in FIG. 13D.

In example embodiments, the lower contact structure 180A penetrating through the first lower insulating layer 194, the backside gate structure 160_1, and the first lower insulating layer 194 and connected to the lower source/drain region 150A may be formed after the substrate 101, the active region 105, and the device isolation layer 110.

Thereafter, a second lower insulating layer 195 covering or overlapping the first lower insulating layer 194, the backside gate structure 160_1, and the lower contact structure 180A may be formed, and a backside contact hole BCH penetrating through the second lower insulating layer 195 may be formed.

A backside contact structure 180A, and a backside gate contact structure 190A may be formed to fill the backside contact hole BCH.

Referring to FIG. 2, a third lower insulating layer 196 covering or overlapping the backside contact structure 190A and the backside gate contact structure 190B may be formed, and a second interconnection M2 may be formed by patterning the third lower insulating layer 196 and filing a conductive material.

Referring to FIGS. 2 and 4A-4C together, the first lower metal interconnection M2a (see FIGS. 2 and 4A) connected to the first transistor structure TR1 and the first upper metal interconnection M1a connected to the fourth transistor structure TR4 (see FIGS. 2 and 4B) may be electrically connected to each other in regions other than the region illustrated in the drawing.

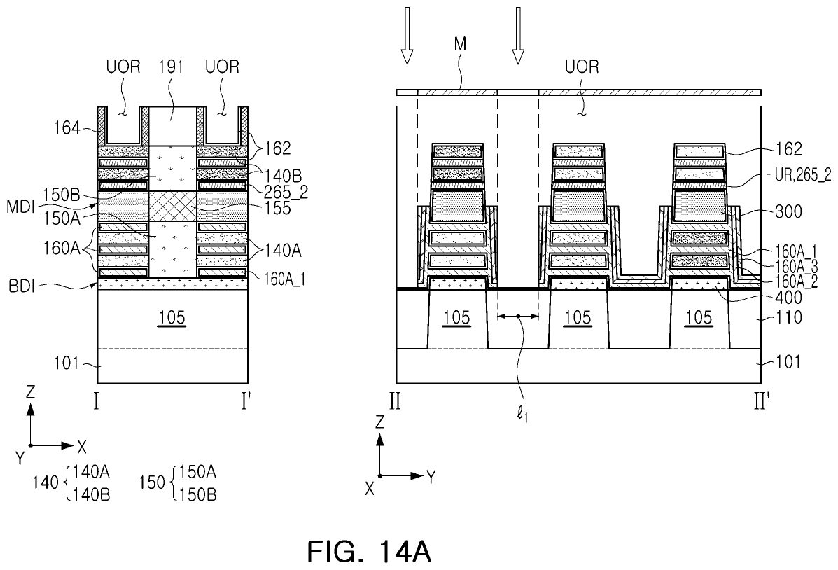

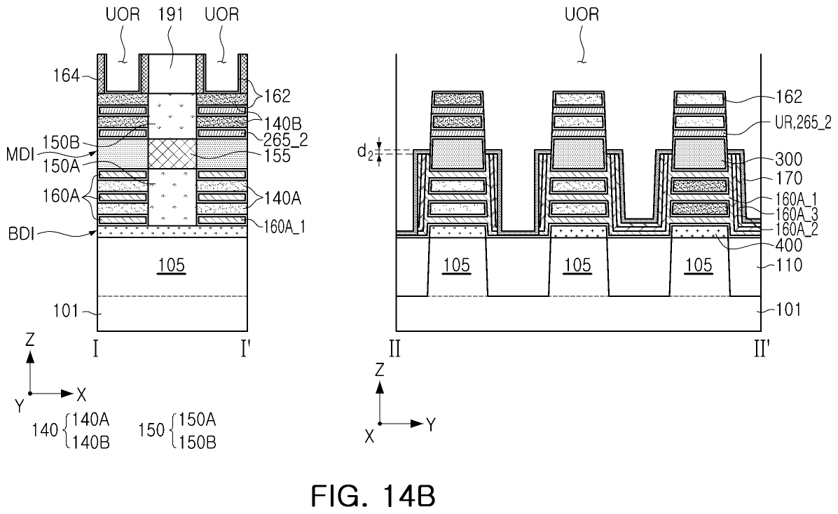

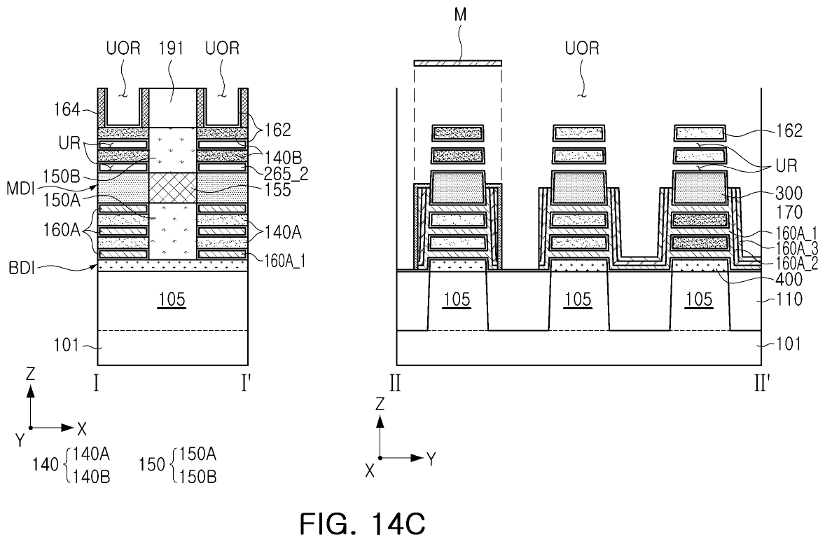

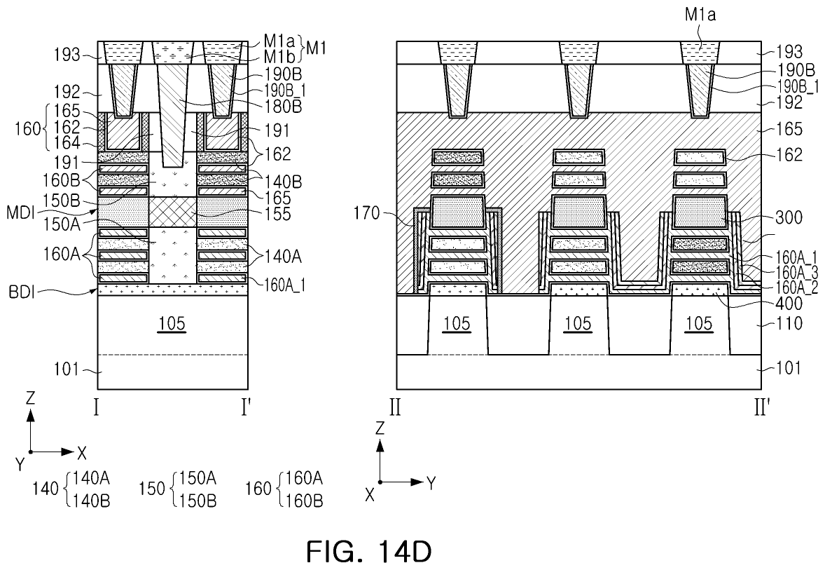

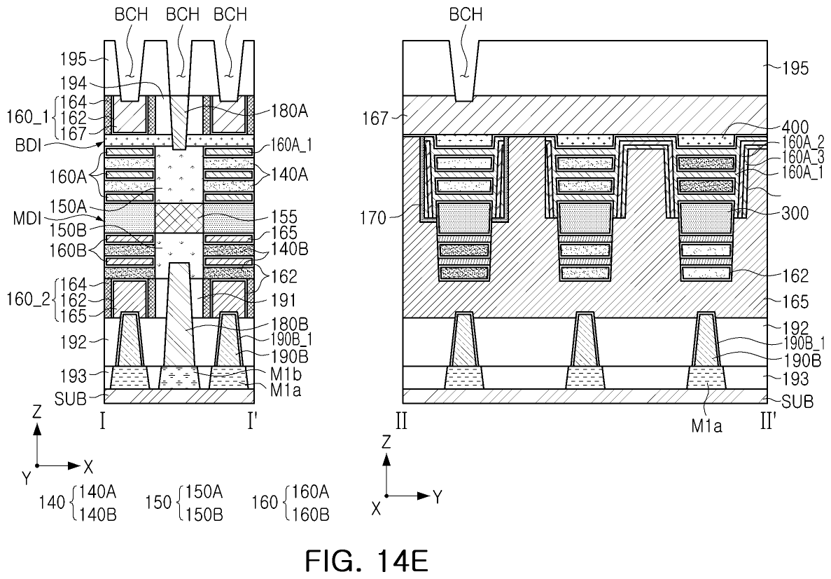

FIGS. 14A to 14E are cross-sectional diagrams illustrating processes of a method of manufacturing a semiconductor device in order according to example embodiments.

FIGS. 14A to 14E are diagrams continued from the manufacturing method described with reference to FIGS. 12A to 12E to describe the method of manufacturing the semiconductor devices 100B and 200B according to the example embodiments.

Referring to FIG. 14A, a mask pattern M may be disposed on a predetermined channel structure 140 and may be etched through the mask pattern M, thereby cutting the lower gate electrode 160A_1 connected between adjacent lower transistors in the second direction, for example, X-direction.

For electrical insulation between upper/lower transistors spaced apart from each other in the vertical direction (Z-direction), and also for electrical insulation between the lower transistor and adjacent lower transistors in the second direction, for example, Y-direction, the lower gate electrode 160A_1 connected between adjacent lower transistors in the second direction may be cut through a method such as lithography. The first distance 11 between the cut-out lower gate electrodes 160A_1 may be about 10 nm or more, for example, 10 nm to 20 nm, 10 nm to 15 nm, or 15 nm to 20 nm. Accordingly, at least a portion of the insulating layer formed on the device isolation layer 110 may be exposed.

The external side surfaces of the lower gate electrode 160A_1 and the plurality of lower gate electrode layers 160A_2 and 160A_3 of the predetermined lower transistor may be perpendicular to the upper surface of the substrate 101, but example embodiments thereof is not limited thereto. For example, referring to FIG. 6B, the external side surface of the lower gate electrode 160A_1 and the plurality of lower gate electrode layers 160A_2 and 160A_3 of the predetermined lower transistor may form an oblique line with the upper surface of the substrate 101.

Referring to FIG. 14B, similarly to the process in FIG. 13A, a gate isolation insulating layer 170 covering the surface of lower gate electrode 160A_1, and plurality of lower gate electrode layers 160A_2, 160A_3, and at least a portion of the insulating layer formed on the device isolation layer 110 may be formed.

The gate isolation insulating layer 170 may be conformally formed on the surface of lower gate electrode 160A_1, and the plurality of lower gate electrode layers 160A_2 and 160A_3. The gate isolation insulating layer 170 may be formed, for example, by atomic layer deposition (ALD).

Referring to FIG. 14C, similarly to the process in FIG. 13B, the second blocking layer 265_2 in the upper gap region UR may be removed. Thereafter, by forming the mask pattern M on the predetermined channel structure 140, the gate isolation insulating layer 170 may remain only on the predetermined lower transistor. Overlapping descriptions will not be provided.

Referring to FIG. 14D, similarly to FIG. 13C, a gate structure 160 may be formed in the upper gap regions UR. Also, similarly to FIG. 13D, a contact structure 180B, a gate contact structure 190B, and a first interconnection M1 may be formed. Overlapping descriptions will not be provided.

Referring to FIG. 14E, similar to FIG. 13E, the entire structure formed with reference to FIGS. 14A to 14D may be attached to the carrier substrate SUB and a backside process may be performed. Overlapping descriptions will not be provided.

According to the aforementioned example embodiments, by including a gate isolation insulating layer electrically insulating the upper and lower devices spaced apart from each other in the vertical direction and/or electrically insulating the lower devices of each device adjacent in the horizontal direction, a semiconductor device having increased integration density and guaranteed reliability may be provided.

While the example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a substrate;
lower channel layers spaced apart from each other in a vertical direction perpendicular to an upper surface of the substrate and extending in a first direction parallel to the upper surface of the substrate;
upper channel layers on the lower channel layers, and spaced apart from each other in the vertical direction;
a middle dielectric isolation structure between an uppermost lower channel layer among the lower channel layers and a lowermost upper channel layer among the upper channel layers;
a lower gate structure on the lower channel layers;
an upper gate structure on the upper channel layers and that extends in a second direction perpendicular to the first direction;
a gate isolation insulating layer between the lower gate structure and the upper gate structure, in contact with a side surface of the middle dielectric isolation structure on the lower gate structure, and on at least a portion of the lower gate structure;
a lower source/drain region on at least one side of the lower gate structure and electrically connected to the lower channel layers;
an upper source/drain region electrically connected to each of the upper channel layers on at least one side of the upper gate structure and spaced apart from the lower source/drain region in the vertical direction; and
a barrier structure between the lower source/drain region and the upper source/drain region.

2. The semiconductor device of claim 1, wherein the lower gate structure comprises:
a lower gate electrode extending around the lower channel layers and extending in the second direction;
a first lower gate electrode layer on a side surface and a lower surface of the lower gate electrode; and
a second lower gate electrode layer on a side surface and a lower surface of the first lower gate electrode layer.

3. The semiconductor device of claim 2, wherein the gate isolation insulating layer extends along a side surface of the lower gate structure, extends on an upper surface of the lower gate structure, and is in contact with at least a portion of a lower surface of the second lower gate electrode layer.

4. The semiconductor device of claim 2, wherein the lower gate electrode, the first lower gate electrode layer, and the second lower gate electrode layer include different materials.

5. The semiconductor device of claim 1, wherein the lower gate structure comprises:
a lower gate electrode extending around the lower channel layers;
a first lower gate electrode layer on a side surface and a lower surface of the lower gate electrode; and
a second lower gate electrode layer on a side surface and a lower surface of the first lower gate electrode layer, and
wherein the lower gate electrode is in contact with the gate isolation insulating layer, and the first lower gate electrode layer is in contact with the gate isolation insulating layer.

6. The semiconductor device of claim 5, wherein a lowermost end of the lower gate structure and a lowermost end of the upper gate structure are substantially on the same level.

7. The semiconductor device of claim 5,
wherein, in the cross-sectional view in the second direction, the gate isolation insulating layer is in contact with a side surface of the middle dielectric isolation structure on an upper surface of the lower gate structure,
wherein the gate isolation insulating layer extends along a side surface of the second lower gate electrode layer, and
wherein, in a lower portion of the lower gate structure, the gate isolation insulating layer is on a side surface of the lower gate electrode and is on a side surface of the first lower gate electrode layer.

8. The semiconductor device of claim 7, wherein the gate isolation insulating layer extends perpendicularly towards the upper surface of the substrate along a side surface of the lower gate structure.

9. The semiconductor device of claim 7,
wherein the gate isolation insulating layer extends diagonally along a side surface of the lower gate structure with respect to the upper surface of the substrate.

10. The semiconductor device of claim 7, wherein a lower surface of the gate isolation insulating layer and a lowermost end of the lower gate electrode are substantially a same distance from the substrate.

11. The semiconductor device of claim 7, wherein an upper surface of the lower gate structure is between an upper surface of the middle dielectric isolation structure and a lower surface of the middle dielectric isolation structure.

12. The semiconductor device of claim 1, wherein an upper surface of the lower gate structure is between an upper surface of the middle dielectric isolation structure and a lower surface of the middle dielectric isolation structure.

13. The semiconductor device of claim 1,
wherein an upper surface of the lower gate structure has a curved portion, and
wherein at least a portion of the gate isolation insulating layer extends into the curved portion.

14. The semiconductor device of claim 1, wherein the gate isolation insulating layer has a thickness of 5 nm to 15 nm.

15. The semiconductor device of claim 1, wherein the gate isolation insulating layer has a liner shape.

16. A semiconductor device, comprising:
a substrate;
first lower channel layers spaced apart from each other in a vertical direction perpendicular to an upper surface of the substrate and extending in a first direction parallel to the upper surface of the substrate;
first upper channel layers on the first lower channel layers and spaced apart from each other in the vertical direction;
a first middle dielectric isolation structure between an uppermost lower channel layer among the first lower channel layers and a lowermost upper channel layer among the first upper channel layers;
a first lower gate structure including a lower gate electrode on the first lower channel layers;
a first upper gate structure on the first upper channel layers and that extends in a second direction perpendicular to the first direction;
a first lower gate isolation insulating layer between the first lower gate structure and the first upper gate structure;
a lower source/drain region on at least one side of the first lower gate structure and electrically connected to the first lower channel layers, respectively;
an upper source/drain region electrically connected to each of the first upper channel layers on at least one side of the first upper gate structure and spaced apart from the lower source/drain region in the vertical direction;
a barrier structure between the lower source/drain region and the upper source/drain region;
a lower gate contact structure below the first lower gate structure and electrically connected to the lower gate electrode of the first lower gate structure; and
a lower interconnection below the lower gate contact structure and electrically connected to the lower gate contact structure,
wherein the first lower gate isolation insulating layer is in contact with a side surface of the first middle dielectric isolation structure, and
wherein the first lower gate isolation insulating layer extends along a side surface of the first lower gate structure.

17. The semiconductor device of claim 16, further comprising:
second lower channel layers spaced apart from each other in the vertical direction, electrically connected to the lower source/drain region, and adjacent to the first lower channel layers in the first direction;
second upper channel layers on the second lower channel layers, spaced apart from each other in the vertical direction, electrically connected to the upper source/drain region, and adjacent to the first upper channel layers in the first direction;
a second middle dielectric isolation structure between an uppermost lower channel layer among the second lower channel layers and a lowermost upper channel layer among the second upper channel layers;
a second lower gate structure extending around the second lower channel layers;
a second upper gate structure including an upper gate electrode extending around the second upper channel layers on the second lower gate structure and extending in a second direction perpendicular to the first direction;
a second gate isolation insulating layer between the second lower gate structure and the second upper gate structure;
an upper gate contact structure on the second upper gate structure and electrically connected to the upper gate electrode of the second upper gate structure; and
an upper interconnection on the upper gate contact structure and electrically connected to the upper gate contact structure,
wherein the upper interconnection is electrically connected to the lower interconnection.

18. The semiconductor device of claim 16, wherein the first lower gate structure is configured to exchange input/output signals through the lower interconnection.

19. A semiconductor device, comprising:
a lower structure;
an upper structure;
middle dielectric isolation structures extending in a first direction between the lower structure and the upper structure and spaced apart from each other in a second direction perpendicular to the first direction; and
a gate isolation insulating layer between at least a portion of the lower structure and at least a portion of the upper structure, and extending from a side surface of at least a portion of the middle dielectric isolation structures toward a lower end of the lower structure,
wherein the lower structure includes:
a lower source/drain regions spaced apart from each other in the first direction;
lower active layers spaced apart from each other in a vertical direction, between lower source/drain regions, and electrically connected to the lower source/drain regions; and
a lower gate structure including a first lower gate structure having a first lower gate electrode that extends in a second direction perpendicular to the first direction, and a second lower gate structure including a second lower gate electrode electrically insulated from the first lower gate electrode by the gate isolation insulating layer,
wherein the upper structure includes:
upper source/drain regions spaced apart from each other in the first direction and overlapping the lower source/drain regions in the vertical direction;
upper active layers spaced apart from each other in the vertical direction, between the upper source/drain regions, connected to the upper source/drain regions, and overlapping the lower active layers in the vertical direction; and
an upper gate structure extending in the second direction and overlapping the lower gate structure in the vertical direction,
wherein the gate isolation insulating layer is in contact with a side surface of the middle dielectric isolation structure on the second lower gate structure,
wherein the gate isolation insulating layer extends along a side surface of the second lower gate structure, and
wherein a lower end of the gate isolation insulating layer is substantially a same distance from a substrate as a lower end of the second lower gate structure and a lower end of the upper structure.

20. The semiconductor device of claim 19, wherein the upper source/drain regions and the lower source/drain regions have different conductivity types.
